(19) United States
(12) Patent Application Publication
(10) Pub. No.: US 2025/0206901 A1
(43) Pub. Date: Jun. 26, 2025

(54) BRUSH MATERIAL FOR SELF-ASSEMBLED FILM

(71) Applicant: NISSAN CHEMICAL CORPORATION, Tokyo (JP)

(72) Inventors: Ryuta MIZUOCHI, Toyama (JP); Shou SHIMIZU, Toyama (JP); Mamoru TAMURA, Toyama (JP)

(73) Assignee: NISSAN CHEMICAL CORPORATION, Tokyo (JP)

(21) Appl. No.: 18/850,938

(22) PCT Filed: Mar. 30, 2023
(86) PCT No.: PCT/JP2023/013054

§ 371 Date: Sep. 25, 2024

(30) Foreign Application Priority Data
Mar. 31, 2022 (JP) 2022-058572

(51) Int. Cl. C08J 5/18; C08F 6/04; C08K 5/3432; C08K 5/3462; C08K 5/357; C08K 11/00

(52) U.S. Cl. CPC C08J 5/18; C08F 6/04; C08K 5/3432; C08K 5/3462; C08K 5/357; C08K 11/00

(57) ABSTRACT

Provided is a brush forming composition used to cause phase separation of a block copolymer of a layer containing the block copolymer formed on a substrate, the brush forming composition containing: a brush polymer, an organic base, and a solvent.

### TECHNICAL FIELD

The present invention relates to a brush forming composition for forming a microphase-separated pattern, and a production method of a phase-separated pattern of a block copolymer and a manufacturing method of a semiconductor device using the brush forming composition.

### BACKGROUND ART

In recent years, in accordance with further miniaturization of a large-scale integrated circuit (LSI), a technique for processing a finer structure has been required. In response to such a demand, an attempt has been made to form a finer pattern using a phase-separated structure formed by self-assembly of a block copolymer in which incompatible polymers are bonded to each other. For example, a pattern forming method, in which an underlayer film forming composition is applied onto a substrate to form an underlayer film formed of the composition, a self-assembled film containing a block copolymer in which two or more kinds of polymers are bonded to each other is formed on a surface of the underlayer film, the block copolymer in the self-assembled film is subjected to phase separation, and a phase of at least one kind of polymers constituting the block copolymer is selectively removed, has been proposed.

Patent Literature 1 discloses a primer containing a resin component in which 20 mol % to 80 mol % of structural units of the entire components are structural units derived from an aromatic ring-containing monomer.

Patent Literature 2 discloses an underlayer film forming composition of a self-assembled film containing a polymer having a unit structure of an aromatic vinyl compound which may be substituted, such as styrene, vinylnaphthalene, acenaphthylene, or vinylcarbazole, in an amount of 20 mol % or more with respect to the entire unit structure of the polymer and having a unit structure of a polycyclic aromatic vinyl compound in an amount of 1 mol % or more with respect to the entire unit structure of the aromatic vinyl compound.

### CITATION LIST

### Patent Literature

Patent Literature 1: WO 2012/036121 A
Patent Literature 2: WO 2014/097993 A

### SUMMARY OF INVENTION

### Technical Problem

When the primer or the underlayer film forming composition (hereinafter, referred to as a “brush forming composition”) is applied onto a substrate to form an underlayer film, a precursor film of the underlayer film is exposed to a solvent in order to remove a film component (for example, a polymer) having weak adhesion to the substrate. This is because when a film component having weak adhesion remains in the underlayer film, the underlayer film is mixed with a self-assembled film. Note that, when there are a large amount of film components having weak adhesion to the substrate, a thickness of the underlayer film after being exposed to a solvent is thin.

On the other hand, when the thickness of the underlayer film formed of the brush forming composition is thin, the function as the underlayer film becomes insufficient.

Therefore, a thick underlayer film is required even when exposed to a solvent.

The present invention has been made in view of the above circumstances, and an object thereof is to provide a brush forming composition capable of forming a thick underlayer film even when exposed to a solvent.

In addition, an object of the present invention is to provide a production method of a phase-separated pattern of a block copolymer and a manufacturing method of a semiconductor device using the brush forming composition.

### Solution to Problem

As a result of intensive studies to solve the above problems, the present inventors have found that the thickness of the underlayer film after exposure to a solvent can be increased by allowing the brush forming composition to contain an organic base as compared with the case of not containing an organic base, thereby completing the present invention having the following gist.

That is, the present invention encompasses the following.
[1]A brush forming composition used to cause phase separation of a block copolymer of a layer containing the block copolymer formed on a substrate, the brush forming composition containing:
   a brush polymer, an organic base, and a solvent.
[2] The brush forming composition according to [1], in which the organic base contains a nitrogen atom.
[3] The brush forming composition according to [1] or [2], in which the organic base contains a nitrogen-containing ring.
[4] The brush forming composition according to any one of [1] to [3], in which the organic base is at least one of N-methylmorpholine, N,N-dimethyl-4-aminopyridine, and diazabicycloundecene.
[5] The brush forming composition according to any one of [1] to [4], in which a content of the organic base is 0.1 mass % to 30 mass % with respect to the brush polymer.
[6] The brush forming composition according to any one of [1] to [5], in which a content of the organic base is 0.5 mass % to 15 mass % with respect to the brush polymer.
[7] The brush forming composition according to any one of [1] to [6], in which the brush polymer contains a functional group capable of binding to the substrate.
[8] The brush forming composition according to [7], in which the functional group capable of binding to the substrate is a hydroxy group, an amino group, or a sulfonic acid group.
[9] The brush forming composition according to any one of [1] to [8], in which the brush polymer is an addition polymerization type polymer.
[10] The brush forming composition according to any one of [1] to [9], in which the brush forming composition is an underlayer film forming composition for forming an underlayer film of the layer containing the block copolymer.
[11]A substrate with an underlayer film obtained by exposing, to a solvent, a precursor film of an underlayer film obtained by applying the brush forming composition according to any one of [1] to [10] onto a substrate and heating the brush forming composition.
[12]A production method of a substrate having a phase-separated pattern of a block copolymer, the production method including:
   a step (1) of forming an underlayer film on a substrate using the brush forming composition according to any one of [1] to [10];
   a step (2) of forming a layer containing a block copolymer on the underlayer film; and
   a step (3) of subjecting the block copolymer to phase separation.
[13] The production method according to [12], further including a step of forming an upper layer film on the layer containing the block copolymer between the step (2) and the step (3).
[14] The production method according to [12] or [13], in which the step (1) includes:
   a treatment in which the brush forming composition is applied onto the substrate;
   a treatment in which the brush forming composition applied onto the substrate is heated to form a precursor film of an underlayer film; and
   a treatment in which the precursor film of the underlayer film is exposed to a solvent to obtain the underlayer film.
[15]A manufacturing method of a semiconductor device, the manufacturing method including:
   a step (1) of forming an underlayer film on a substrate using the brush forming composition according to any one of [1] to [10];
   a step (2) of forming a layer containing a block copolymer on the underlayer film;
   a step (3) of subjecting the block copolymer to phase separation;
   a step (4) of removing a portion of the phase-separated block copolymer; and a step (5) of etching the substrate.
[16] The manufacturing method according to [15], further including a step of forming an upper layer film on the layer containing the block copolymer between the step (2) and the step (3).
[17] The manufacturing method according to [15] or [16], in which the step (1) includes:
   a treatment in which the brush forming composition is applied onto the substrate;
   a treatment in which the brush forming composition applied onto the substrate is heated to form a precursor film of an underlayer film; and
   a treatment in which the precursor film of the underlayer film is exposed to a solvent to obtain the underlayer film.

### Advantageous Effects of Invention

According to the present invention, it is possible to provide a brush forming composition capable of forming a thick underlayer film even when exposed to a solvent. In addition, according to the present invention, an object of the present invention is to provide a production method of a phase-separated pattern of a block copolymer and a manufacturing method of a semiconductor device using the brush forming composition.

### DESCRIPTION OF EMBODIMENTS

### (Brush Forming Composition)

A brush forming composition according to an embodiment of the present invention may contain a brush polymer, an organic base, and a solvent, and may further contain other components as necessary.

The brush forming composition is used to cause phase separation of a block copolymer of a layer containing a block copolymer formed on a substrate.

A film formed of the brush forming composition is used as an underlayer film for causing phase separation of a block copolymer of a layer containing a block copolymer formed on a substrate.

The brush forming composition is, for example, a composition containing a polymer chain capable of directly binding to a substrate surface. A film or layer formed by arranging a polymer chain on a substrate in a brush shape may be referred to as a brush layer.

The brush forming composition is, for example, an underlayer film forming composition for forming an underlayer film of a layer containing a block copolymer.

In addition, the film formed of the brush forming composition serves as, for example, a guide for controlling a generation position of a polymer phase formed by self-assembly. For example, the film formed of the brush forming composition has an uneven structure, and is a side wall of a concave portion in a physical guide (grapho-epitaxy) for forming a microphase-separated pattern in the concave portion. In addition, for example, the film formed of the brush forming composition is a chemical guide (chemical-epitaxy) that is formed in an underlayer of a self-assembling material and controls a formation position of the microphase-separated pattern based on a difference in surface energy.

### <Organic Base>

Since the brush forming composition contains an organic base, when the precursor film of the underlayer film obtained using the brush forming composition is exposed to a solvent, and then the underlayer film is formed, a thicker film can be obtained compared to when the brush forming composition does not contain an organic base. That is, a thick underlayer film can be obtained even when exposed to a solvent.

An atom constituting the organic base is not particularly limited, and the organic base contains, for example, a nitrogen atom.

Examples of the atom constituting the organic base include a carbon atom, an oxygen atom, a nitrogen atom, and an oxygen atom.

The organic base is, for example, an organic compound having pKa of a conjugate acid of 6 to 50.

The organic base may be a salt or may not be a salt.

A molecular weight of the organic base is not particularly limited, and may be, for example, 40 to 500.

The organic base is, for example, a liquid or a solid at 25° C.

The organic base may contain, for example, a nitrogen-containing ring or may not contain a nitrogen-containing ring.

The number of nitrogen atoms in the nitrogen-containing ring may be 1, 2, or 3 or more, and is preferably 1 or 2. The nitrogen-containing ring contains a nitrogen atom and a carbon atom as atoms constituting the ring, and may further contain an oxygen atom. Here, the atom constituting the ring refers to an atom that directly contributes to a ring structure. When morpholine is described as an example, one nitrogen atom, one oxygen atom, and four carbon atoms correspond to atoms constituting a ring of morpholine, and a hydrogen atom is not considered to be the atom constituting the ring. The nitrogen-containing ring may have a double bond or may not have a double bond. When the nitrogen-containing ring has a double bond, the double bond may be a carbon-carbon double bond or may be a carbon-nitrogen double bond. When the nitrogen-containing ring has a double bond, the number of double bonds is not particularly limited, and is, for example, 1 to 3.

Examples of the organic base include compounds represented by the following Formulas (I) to (V) and a nitrogen-containing polycyclic compound.

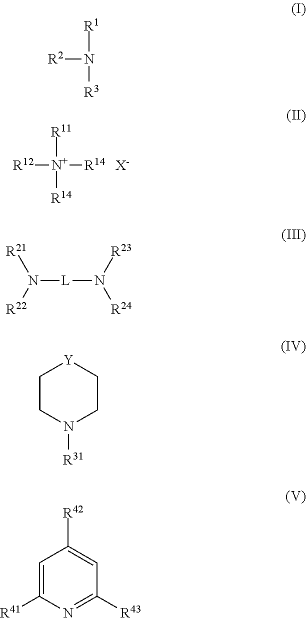

[In Formula (I), R¹ to R³ each independently represent a hydrogen atom, an alkyl group having 1 to 6 carbon atoms, or a hydroxyalkyl group having 1 to 6 carbon atoms, where at least one of R¹ to R³ is a group other than a hydrogen atom, R² and R³ may form a ring structure together with N, and methylene groups of the alkyl group having 1 to 6 carbon atoms and the hydroxyalkyl group having 1 to 6 carbon atoms in R¹ to R³ may be substituted with —O—, except when R² and R³ form a ring structure together with N,
in Formula (II), R¹¹ to R¹⁴ each independently represent a hydrogen atom, an alkyl group having 1 to 20 carbon atoms, a hydroxyalkyl group having 1 to 6 carbon atoms, or an aralkyl group having 7 to 12 carbon atoms, and X-represents a halogen anion or a hydroxy anion,
in Formula (III), R²¹ to R²⁴ each independently represent a hydrogen atom, an alkyl group having 1 to 6 carbon atoms, or a hydroxyalkyl group having 1 to 6 carbon atoms, and L represents an alkylene group having 1 to 5 carbon atoms,
in Formula (IV), Y represents NR³², O, or S, R³¹ and R³² each independently represent a hydrogen atom, an alkyl group having 1 to 4 carbon atoms, a hydroxyalkyl group having 1 to 4 carbon atoms, an aminoalkyl group having 1 to 4 carbon atoms, or an alkyl sulfonate group having 1 to 4 carbon atoms, and
in Formula (V), R⁴¹ to R⁴³ each independently represent a hydrogen atom, an alkyl group having 1 to 6 carbon atoms, or —N(R⁵¹)(R⁵²) (R⁵¹ and R⁵² each independently represent a hydrogen atom or an alkyl group having 1 to 6 carbon atoms).]

Examples of the compound represented by Formula (I) include the following compounds.
(I-1) Primary amine: propylamine, butylamine, pentylamine, 2-methylbutylamine, 2-aminoethanol, 3-amino-1-propanol, aminoethoxyethanol, cyclohexylamine, and cyclopentylamine
(I-2) Secondary amine: diethylamine, dipropylamine, dibutylamine, dimethanolamine, diethanolamine, biperidine, and pyrrolidine
(I-3) Tertiary amine: triethylamine, tripropylamine, N-methyldiethylamine, trimethanolamine, and triethanolamine

Examples of the compound represented by Formula (II) include the following compounds.
Tetramethylammonium hydroxide
Triethylmethylammonium hydroxide
Tetraethylammonium hydroxide
Tetrapropylammonium hydroxide
Tetrabutylammonium hydroxide
Tetrabutylammonium fluoride
Tetrabutylammonium chloride
Tetrabutylammonium bromide
Tetrabutylammonium iodide
Tetrahexylammonium hydroxide
Hexadecyltrimethylammonium hydroxide
Choline
Benzyltrimethylammonium hydroxide
Benzyltriethylammonium hydroxide
Tris(2-hydroxyethyl)methylammonium hydroxide

Examples of the compound represented by Formula (III) include the following compounds.
Ethylenediamine
1,2-Diaminopropane
1,3-Diaminopropane
N,N,N′,N′-tetramethylethylenediamine
N,N,N′,N′-tetraethylethylenediamine
N,N,N′,N′-tetrapropylethylenediamine
N,N,N′,N′-tetraisopropylethylenediamine
N,N,N′,N′-tetrabutylethylenediamine
N,N,N′,N′-tetraisobutylethylenediamine
N,N,N′,N′-tetramethyl-1,2-propylenediamine
N,N,N′,N′-tetraethyl-1,2-propylenediamine
N,N,N′,N′-tetrapropyl-1,2-propylenediamine
N,N,N′,N′-tetraisopropyl-1,2-propylenediamine
N,N,N′,N′-tetramethyl-1,3-propylenediamine
N,N,N′,N′-tetraethyl-1,3-propylenediamine
N,N,N′,N′-tetrapropyl-1,3-propylenediamine
N,N,N′,N′-tetraisopropyl-1,3-propylenediamine
N,N,N′,N′-tetraisobutyl-1,3-propylenediamine
N,N,N′,N′-tetramethyl-1,2-butylene diamine
N,N,N′,N′-tetraethyl-1,2-butylene diamine
N,N-Dimethylaminoethylamine
N,N-Diethylaminoethylamine
N,N-Dimethylaminopropylamine
N,N-Diethylaminopropylamine
N-Methylaminoethylamine
N-Ethylaminoethylamine
N-(2-aminoethylamino)ethanol

Examples of the compound represented by Formula (IV) include piperazine, 1-methylpiperazine, N,N′-dimethylpiperazine, 1-ethylpiperazine, N,N′-diethylpiperazine, 1-(2-hydroxyethyl)piperazine, 1,4-bis(2-hydroxyethyl)piperazine, N-(2-aminoethyl)piperazine, 1,4-bis(2-aminoethyl)piperazine, 2-[4-(2-hydroxyethyl)-1-piperazinyl]ethanesulfonic acid, piperazine-1,4-bis(2-ethanesulfonic acid), morpholine, 4-methylmorpholine, 4-ethylmorpholine, 4-(2-aminoethyl)morpholine, 4-(2-hydroxyethyl)morpholine, 2-morpholinoethanesulfonic acid, and 3-morpholinopropanesulfonic acid.

Examples of the compound represented by Formula (V) include pyridine, collidine, lutidine, 2-aminopyridine, 4-aminopyridine, 2,6-diaminopyridine, N,N-dimethyl-4-aminopyridine, and N,N-diethyl-4-aminopyridine.

The nitrogen-containing polycyclic compound is not particularly limited as long as it is a polycyclic compound containing a nitrogen atom, and examples thereof include 1,8-diazabicyclo[5.4.0]undecene-7 (diazabicycloundecene, DBU), 1,5-diazabicyclo[4.3.0]nonene-5 (DBN), 1,4-diazabicyclo[2.2.2]octane (DABCO), 1,5,7-triazabicyclo[4.4.0]decene-5 (TBD), and 7-methyl-1,5,7-triazabicyclo[4.4.0]decene-5 (MTBD).

A content of the organic base in the brush forming composition is not particularly limited, and is preferably 0.1 mass % to 30 mass %, more preferably 0.3 mass % to 25 mass %, and particularly preferably 0.5 mass % to 15 mass %, with respect to the brush polymer, from the viewpoint of suitably obtaining the effect of the present invention.

### <Brush Polymer>

The brush polymer is not particularly limited as long as it is a brush polymer used for forming an underlayer film.

Examples of the brush polymer include a polymer contained in a neutral wet bottom surface described in JP 2011-515537 A. Examples of such a polymer include a random copolymer described in claim 15 of JP 2011-515537 A and a grafted blend of a plurality of homopolymers described in claim 16 of JP 2011-515537 A. The contents of JP 2011-515537 A are hereby incorporated in their entireties by reference, to the extent that they have been disclosed herein.

Other examples of the brush polymer include a random copolymer described in JP 2011-518652 A. An example of the random copolymer described in JP 2011-518652 A is photocrosslinkable random PS-r-PMMA described in paragraph [0028] The contents of JP 2011-518652 A are hereby incorporated in their entireties by reference, to the extent that they have been disclosed herein.

Other examples of the brush polymer include a resin in which 20 mol % to 80 mol % of structural units of the entire structural units are structural units derived from an aromatic ring-containing monomer. Such a resin is, for example, a resin component contained in a primer described in WO 2012/036121 A. The contents of WO 2012/036121 A are hereby incorporated in their entireties by reference, to the extent that they have been disclosed herein.

Other examples of the brush polymer include a random copolymer described in claim 1 of JP 2013-166934 A. The contents of JP 2013-166934 A are hereby incorporated in their entireties by reference, to the extent that they have been disclosed herein.

Other examples of the brush polymer include a polymer having 0.2 mol % or more of a unit structure of a polycyclic aromatic vinyl compound with respect to the entire unit structure. Examples of such polymers include a polymer contained in an underlayer film forming composition described in WO 2014/097993 A. The contents of WO 2014/097993 A are hereby incorporated in their entireties by reference, to the extent that they have been disclosed herein.

Other examples of the brush polymer include a polymer [for example, poly(alkyl acrylate) containing a functional group capable of reacting with a semiconductor substrate] contained in a brush backfill composition described in JP 2015-130496 A. The contents of JP 2015-130496 A are hereby incorporated in their entireties by reference, to the extent that they have been disclosed herein.

Other examples of the brush polymer include an addition polymer described in claim 1 of JP 2016-148024 A. The contents of JP 2016-148024 A are hereby incorporated in their entireties by reference, to the extent that they have been disclosed herein.

Other examples of the brush polymer include a polymer contained in a pinning material described in claim 1 of JP 2016-528713 A. Examples of such a polymer include a polymer described in claim 3 of JP 2016-528713 A. The contents of JP 2016-528713 A are hereby incorporated in their entireties by reference, to the extent that they have been disclosed herein.

Other examples of the brush polymer include an acid-sensitive copolymer containing an acid-decomposable group, an attachment group, and a functional group described in claim 1 of JP 2018-139007 A. The contents of JP 2018-139007 A are hereby incorporated in their entireties by reference, to the extent that they have been disclosed herein.

Other examples of the brush polymer include a hydrophobic polymer brush precursor described in claim 1 of JP 2018-503241 A. The contents of JP 2018-503241 A are hereby incorporated in their entireties by reference, to the extent that they have been disclosed herein.

The brush polymer preferably contains a functional group capable of binding to a substrate.

Examples of the functional group capable of binding to the substrate include a hydroxy group, an amino group, and a sulfonic acid group.

The brush polymer may contain a functional group capable of binding to a substrate at a terminal of a polymer chain or at a location other than the terminal of the polymer chain.

A method for introducing a functional group capable of binding to a substrate into a terminal of a polymer chain is not particularly limited, and examples thereof include a method using a compound containing a functional group capable of binding to a substrate in a polymerization initiator or a chain transfer agent in a case of an addition polymerization type polymer.

The brush polymer is preferably an addition polymerization type polymer.

The addition polymerization type polymer is obtained by, for example, polymerizing one or more kinds of radically polymerizable monomers.

The radically polymerizable monomer is not particularly limited, and examples thereof include a (meth)acrylic compound and an aromatic group-containing vinyl compound.

Examples of the (meth)acrylic compound include (meth)acrylic acid and (meth)acrylic acid ester. Examples of the (meth)acrylic acid ester include methyl (meth)acrylate, ethyl (meth)acrylate, methyl (meth)acrylate, ethyl (meth)acrylate, propyl (meth)acrylate, isopropyl (meth)acrylate, n-butyl (meth)acrylate, sec-butyl (meth)acrylate, and tert-butyl (meth)acrylate.

Examples of the aromatic group-containing vinyl compound include styrene, α-methylstyrene, 2-methylstyrene, 3-methylstyrene, 4-methylstyrene, 4-t-butylstyrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, vinylcyclohexane, 4-vinylbenzyl chloride, 1-vinylnaphthalene, 4-vinylbiphenyl, 1-vinyl-2-pyrrolidone, 9-vinylanthracene, and vinylpyridine.

### <<Polymer (P)>>

The brush polymer is preferably a polymer (P) containing the following Structural Units (A) and (B) from the viewpoint of being able to induce a microphase-separated structure of the block copolymer perpendicularly to the substrate.
Structural unit (A): Structural unit derived from a (meth)acrylic compound containing a (meth)acryloyl group and a functional group capable of binding to a substrate
Structural unit (B): Structural unit derived from an aromatic group-containing vinyl compound

A molar ratio of the structural unit (A) to all structural units in the polymer (P) is more than 0% and 5% or less.

When the molar ratio of the structural unit (A) to all the structural units in the polymer (P) is more than 0% and 5% or less, a film that induces a microphase-separated structure of the block copolymer perpendicularly to the substrate can be formed. When the molar ratio of the structural unit (A) to all structural units in the polymer (P) is more than 5%, an arrangement of the microphase-separated structure of the block copolymer is disturbed, and the microphase-separated structure of the block copolymer cannot be induced perpendicularly to the substrate.

The polymer (P) is not particularly limited as long as it contains the structural units (A) and (B), and is preferably an addition polymer obtained by polymerization of a compound having a polymerizable unsaturated group. Examples of the polymerizable unsaturated group include an ethylenically unsaturated group. Examples of the ethylenically unsaturated group include a vinyl group, an allyl group, a propargyl group, a butenyl group, an ethynyl group, a phenylethynyl group, a maleimide group, a nadiimide group, and a (meth)acryloyl group.

The polymer (P) is, for example, a random copolymer.

The polymer (P) may contain a structural unit other than the structural units (A) and (B).

The structural unit (A) is a structural unit derived from a (meth)acrylic compound.

The (meth)acrylic compound has a (meth)acryloyl group.

The (meth)acrylic compound contains a functional group capable of binding to a substrate.

The (meth)acryloyl group is a notation indicating an acryloyl group and a methacryloyl group. The acryloyl group refers to a group represented by CH₂═CH—CO—, and the methacryloyl group refers to a group represented by CH₂═C(CH₃)—CO—.

Examples of the functional group capable of binding to the substrate include, but are not limited to, a hydroxy group, an amino group, and a sulfonic acid group.

The number of functional groups capable of binding to a substrate in the structural unit (A) may be 1 or 2 or more, and is preferably 1.

The number of (meth)acryloyl groups in the (meth)acrylic compound may be 1 or 2 or more, and is preferably 1.

The structural unit (A) is a structural unit different from the structural unit (B). Therefore, the structural unit (A) does not have an aromatic ring.

The structural unit (A) in the polymer (P) may be one kind or two or more kinds.

The structural unit (A) preferably includes a structural unit (A-1) represented by the following Formula (1).

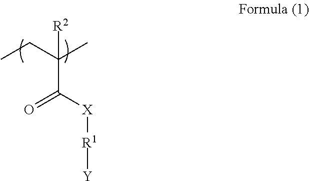

(In Formula (1), X represents —O— or —NH—, Y represents a hydroxy group, an amino group, or a sulfonic acid group, R¹ represents an alkylene group having 1 to 10 carbon atoms which may be substituted with a halogen atom, and R² represents a hydrogen atom or a methyl group.)

The amino group is preferably a primary amino group or a secondary amino group.

The primary amino group refers to a monovalent functional group (—NH₂) obtained by removing a hydrogen atom from ammonia.

The secondary amino group refers to a monovalent functional group (—NHR (in the formula, R represents an organic group)) obtained by removing a hydrogen atom from a primary amine. R represents, for example, an alkyl group having 1 to 6 carbon atoms.

The alkylene group having 1 to 10 carbon atoms which may be substituted with a halogen atom may be linear, branched, or cyclic.

Examples of the halogen atom include a fluorine atom, a chlorine atom, a bromine atom, and an iodine atom.

The number of halogen atoms in the alkylene group having 1 to 10 carbon atoms substituted with a halogen atom may be 1 or 2 or more.

The alkylene group having 1 to 10 carbon atoms may be a linear or branched alkylene group, and examples thereof include a methylene group, an ethylene group, a 1,3-propylene group (trimethylene group), a 1-methylethylene group (1,2-propylene group), a 1,4-butylene group, a 1-ethylethylene group, a 1-methylpropylene group, a 2-methylpropylene group, a 1,5-pentylene group, a 1-methylbutylene group, a 2-methylbutylene group, a 1,1-dimethylpropylene group, a 1,2-dimethylpropylene group, a 1-ethylpropylene group, a 2-ethylpropylene group, a 1,6-hexylene group, a 1,4-cyclohexylene group, a 1,8-octylene group, a 2-ethylocylene group, a 1,9-nonylene group, and a 1,10-decylene group.

The molar ratio of the structural unit (A) to all structural units in the polymer (P) is more than 0% and 5% or less, preferably 0.1% or more and 5% or less, more preferably 0.3% or more and 4.5% or less, and particularly preferably 0.5% or more and 4.0% or less.

Examples of the (meth)acrylic compound include a compound represented by the following Formula (1-1).

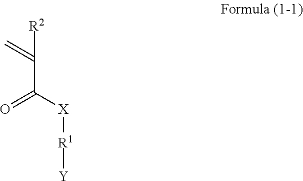

(In Formula (1-1), X represents —O— or —NH—, Y represents a hydroxy group, an amino group, or a sulfonic acid group, R¹ represents an alkylene group having 1 to 10 carbon atoms which may be substituted with a halogen atom, and R² represents a hydrogen atom or a methyl group.)

Examples of the (meth)acrylic compound include hydroxy group-containing (meth)acrylate, amino group-containing (meth)acrylate, sulfonic acid group-containing (meth)acrylate, hydroxy group-containing (meth)acrylamide, and sulfonic acid group-containing (meth)acrylamide.

Examples of the hydroxy group-containing (meth)acrylate include 2-hydroxyethyl (meth)acrylate, 2-hydroxypropyl (meth)acrylate, 3-hydroxypropyl (meth)acrylate, 4-hydroxybutyl (meth)acrylate, 6-hydroxyhexyl (meth)acrylate, 8-hydroxyoctyl (meth)acrylate, and 1,4-cyclohexanedimethanol mono(meth)acrylate.

Examples of the amino group-containing (meth)acrylate include a primary amino group-containing (meth)acrylate and a secondary amino group-containing (meth)acrylate.

Examples of the primary amino group-containing (meth)acrylate include aminomethyl (meth)acrylate and aminoethyl (meth)acrylate.

Examples of the secondary amino group-containing (meth)acrylate include t-butylaminoethyl (meth)acrylate and t-butylaminopropyl (meth)acrylate.

Examples of the sulfonic acid group-containing (meth)acrylate include 2-sulfoethyl (meth)acrylate and 3-sulfopropyl (meth)acrylate.

Examples of the hydroxy group-containing (meth)acrylamide include N-(hydroxymethyl) (meth)acrylamide, N-(2-hydroxyethyl) (meth)acrylamide, and N-(4-hydroxybutyl) (meth)acrylamide.

The structural unit (B) is a structural unit derived from an aromatic group-containing vinyl compound.

The aromatic ring of the aromatic group-containing vinyl compound may be an aromatic hydrocarbon ring or may be an aromatic heterocyclic ring, and an aromatic hydrocarbon ring is preferable.

Examples of the aromatic hydrocarbon ring include a benzene ring, a naphthalene ring, and an anthracene ring.

The aromatic group-containing vinyl compound does not contain, for example, a functional group capable of binding to a substrate.

The aromatic group-containing vinyl compound does not contain, for example, a hydroxy group, an amino group, and a sulfonic acid group.

The structural unit (B) does not contain, for example, a functional group capable of binding to a substrate.

The structural unit (B) does not contain, for example, a hydroxy group, an amino group, and a sulfonic acid group.

The structural unit (B) in the polymer (P) may be one kind or two or more kinds.

The structural unit (B) preferably includes a structural unit (B-1) represented by the following Formula (2).

The structural unit (B) preferably includes a structural unit (B-2) represented by the following Formula (3).

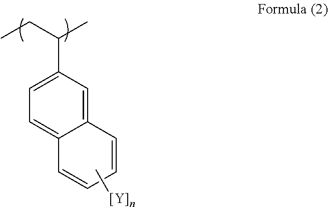

(In Formula (2), n Y's each independently represent a halogen atom, an alkyl group, an alkoxy group, an alkoxycarbonyl group, or a thioalkyl group, and n represents an integer of 0 to 7.)

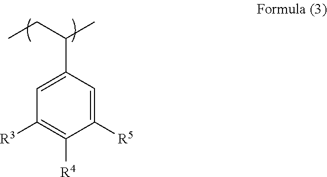

(In Formula (3), R³ to R⁵ each independently represent a hydrogen atom or a tert-butyl group, where one or two of R³ to R⁵ represent tert-butyl groups.)

Examples of the halogen atom in Y in Formula (2) include a fluorine atom, a chlorine atom, a bromine atom, and an iodine atom.

The alkyl group in Y in Formula (2) is preferably an alkyl group having 1 to 15 carbon atoms, more preferably an alkyl group having 1 to 10 carbon atoms, still more preferably an alkyl group having 1 to 6 carbon atoms, and particularly preferably an alkyl group having 1 to 3 carbon atoms. The alkyl group may be linear, branched, or cyclic.

The alkoxy group in Y in Formula (2) is preferably an alkoxy group having 1 to 15 carbon atoms, more preferably an alkoxy group having 1 to 10 carbon atoms, still more preferably an alkoxy group having 1 to 6 carbon atoms, and particularly preferably an alkoxy group having 1 to 3 carbon atoms. The alkyl group in the alkoxy group may be linear, branched, or cyclic.

The alkoxycarbonyl group in Y in Formula (2) is preferably an alkoxycarbonyl group having 2 to 15 carbon atoms, more preferably an alkoxycarbonyl group having 2 to 10 carbon atoms, still more preferably an alkoxycarbonyl group having 2 to 6 carbon atoms, and particularly preferably an alkoxycarbonyl group having 2 to 3 carbon atoms. The alkyl group in the alkoxycarbonyl group may be linear, branched, or cyclic.

Examples of the thioalkyl group in Y in Formula (2) include a group in which —O— of the alkoxy group is substituted with —S—.

A molar ratio of the structural unit (B) to all structural units in the polymer (P) is not particularly limited, and is preferably 80% or more and less than 100%, more preferably 90% or more and less than 100%, and particularly preferably more than 95% and less than 100%.

A molar ratio of the structural unit (A) to the structural unit (B) (structural unit (A):structural unit (B)) in the polymer (P) is not particularly limited, and is preferably 1:200 to 1:10, and more preferably 1:150 to 1:20.

When the polymer (P) contains the structural unit (B-1) represented by Formula (2), a molar ratio of the structural unit (A) to the structural unit (B-1) (structural unit (A):structural unit (B-1)) in the polymer (P) is not particularly limited, and is preferably 1:100 to 1:5, and more preferably 1:75 to 1:10.

When the polymer (P) contains the structural unit (B-2) represented by Formula (3), a molar ratio of the structural unit (A) to the structural unit (B-2) (structural unit (A):structural unit (B-2)) in the polymer (P) is not particularly limited, and is preferably 1:100 to 1:5, and more preferably 1:75 to 1:10.

When the polymer (P) contains the structural unit (B-1) represented by Formula (2) and the structural unit (B-2) represented by Formula (3), a molar ratio of the structural unit (B-1) to the structural unit (B-2) in the polymer (P) (structural unit (B-1):structural unit (B-2)) is not particularly limited, and is preferably 1.0:0.1 to 0.1:1.0, more preferably 1.0:0.5 to 0.5:1.0, and particularly preferably 1.0:0.7 to 0.7:1.0.

Examples of the aromatic group-containing vinyl compound include a compound represented by the following Formula (2-1) and a compound represented by the following Formula (3-1).

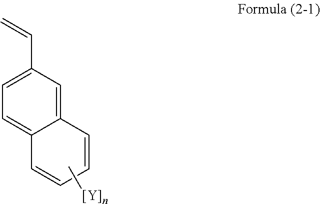

(In Formula (2-1), n Y's each independently represent a halogen atom, an alkyl group, an alkoxy group, an alkoxycarbonyl group, or a thioalkyl group, and n represents an integer of 0 to 7.)

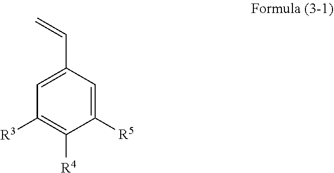

(In Formula (3-1), R³ to R⁵ each independently represent a hydrogen atom or a tert-butyl group, where one or two of R³ to R⁵ represent tert-butyl groups.)

A weight average molecular weight of the brush polymer measured by a gel permeation chromatography (Gel Permeation Chromatography, GPC) method is not particularly limited, and is, for example, 1,000 to 50,000 and preferably 2,000 to 20,000 in terms of polystyrene.

### <<Production Method of Brush Polymer>>

A production method of a brush polymer is not particularly limited.

For example, when the brush polymer is an addition polymerization type polymer, the brush polymer can be produced by polymerizing a monomer by a conventional method, for example, bulk polymerization, solution polymerization, suspension polymerization, or emulsion polymerization. Solution polymerization is particularly preferable, and in this case, for example, polymerization can be performed by adding a desired monomer to a solvent to which a polymerization initiator is added.

For example, when the brush polymer is an addition polymerization type random copolymer, the brush polymer can be produced by copolymerizing various monomers by a conventional method such as bulk polymerization, solution polymerization, suspension polymerization, or emulsion polymerization so as to be copolymerized in an appropriate molar ratio.

Examples of such polymerization include radical polymerization.

The production method of the brush polymer may be a production method by a polymerization method other than radical polymerization. For example, the production method may be a production method by ionic (anionic or cationic) addition polymerization, or a production method by a polycondensation or polyaddition reaction.

The polymer (P) can be produced, for example, by solution polymerization of a monomer mixture containing a (meth)acrylic compound containing a (meth)acryloyl group and a functional group capable of binding to a substrate, and an aromatic group-containing vinyl compound.

### <<Polymerization Initiator>>

As the polymerization initiator, an organic peroxide or a diazo-based compound can be used.

Examples of the organic peroxide include diacyl peroxides, peroxydicarbonates, peroxyesters, and sulfonate peroxides.

Examples of the diacyl peroxides include diacetyl peroxide, diisobutyl peroxide, didecanoyl peroxide, benzoyl peroxide, and succinic acid peroxide.

Examples of the peroxydicarbonates include diisopropyl peroxydicarbonate, di-2-ethylhexyl peroxydicarbonate, and diallyl peroxydicarbonate.

Examples of the peroxyesters include tert-butyl peroxyisobutyrate, tert-butyl neodecanoate, and cumene peroxy neodecanoate.

Examples of the sulfonate peroxides include acetylcyclohexylsulfonyl peroxide.

Examples of the diazo-based compound include 2,2′-azobisisobutyronitrile, 4,4′-azobis(4-cyanovaleric acid), 2,2′-azobis(4-methoxy-2,4-dimethylvaleronitrile), and 2,2′-azobis(2-cyclopropyl propionitrile).

When it is desired to terminate the polymerization in a short time, it is preferable to use a polymerization initiator having a decomposition half-life at 80° C. of 10 hours or shorter. As such a polymerization initiator, benzoyl peroxide and 2,2′-azobisisobutyronitrile are preferable, and 2,2′-azobisisobutyronitrile is more preferable.

The amount of the polymerization initiator used is, for example, 0.0001 to 0.2 equivalents, preferably 0.0005 to 0.1 equivalents, with respect to the total amount of monomers used.

### <<<Solvent>>>

The solvent used for the polymerization is not particularly limited as long as it is a solvent that is not involved in the polymerization reaction and is compatible with the resulting brush polymer, and examples thereof include aromatic hydrocarbons, alicyclic hydrocarbons, aliphatic hydrocarbons, ketones, ethers, esters, amides, sulfoxides, alcohols, and polyhydric alcohol derivatives.

Examples of the aromatic hydrocarbons include benzene, toluene, and xylene.

Examples of the alicyclic hydrocarbons include cyclohexane.

Examples of the aliphatic hydrocarbons include n-hexane and n-octane.

Examples of the ketones include acetone, methyl ethyl ketone, and cyclohexanone.

Examples of the ethers include tetrahydrofuran and dioxane.

Examples of the esters include ethyl acetate and butyl acetate.

Examples of the amides include N,N-dimethylformamide and N,N-dimethylacetamide.

Examples of the sulfoxides include dimethyl sulfoxide.

Examples of the alcohols include methanol and ethanol.

Examples of the polyhydric alcohol derivatives include ethylene glycol monomethyl ether, ethylene glycol monomethyl ether acetate, and propylene glycol monomethyl ether acetate.

These solvents can be used alone or in combination of two or more kinds thereof.

The polymerization temperature is not particularly limited as long as a side reaction such as a transfer reaction or a stop reaction does not occur and is in a temperature range in which the monomer is consumed and the polymerization is completed, and the polymerization is preferably performed in a temperature range of −100° C. or higher and the solvent boiling point or lower.

In addition, a concentration of the monomer in the solvent is not particularly limited, and is usually 1 to 40 mass % and preferably 10 to 30 wt %.

The time for the polymerization reaction can be appropriately selected, and is usually in a range of 2 hours to 50 hours.

### <Solvent>

The solvent contained in the brush forming composition is not particularly limited as long as it is a solvent that dissolves the brush polymer.

Examples of the solvent include propylene glycol monomethyl ether (PGME), propylene glycol monomethyl ether acetate (PGMEA), propylene glycol monopropyl ether, methyl ethyl ketone, ethyl lactate, cyclohexanone, N,N-2-trimethyl propionamide, γ-butyrolactone, N-methyl-2-pyrrolidone, methyl 2-hydroxyisobutyrate, and ethyl 3-ethoxypropionate.

These solvents can be used alone or in combination of two or more kinds thereof.

A content of the solvent in the brush forming composition is not particularly limited, and is, for example, 90 mass % or more and 99.9 mass % or less.

### <Other Components>

It is preferable that the brush forming composition does not contain a crosslinking agent. In the present invention, the brush polymer is reacted with the substrate, such that the film obtained using the brush forming composition becomes a film that is not dissolved in a solvent contained in a self-assembled film forming composition containing a block copolymer. Therefore, the brush forming composition does not need to contain a crosslinking agent.

In the present invention, the phrase “does not contain a crosslinking agent” may include that a crosslinking agent is slightly contained to such an extent that the crosslinking agent does not sufficiently play a role as a crosslinking agent. As an aspect in which the brush forming composition does not contain a crosslinking agent, a content of the crosslinking agent in the brush forming composition is preferably less than 0.1 mass %, more preferably 0.01 mass % or less, and particularly preferably 0.001 mass % or less, with respect to the brush polymer.

Examples of the crosslinking agent include a nitrogen-containing compound containing two to four nitrogen atoms substituted with a methylol group or an alkoxymethyl group.

Examples of the crosslinking agent include hexamethoxymethylmelamine, tetramethoxymethyl glycoluril, tetramethoxymethylbenzoguanamine, 1,3,4,6-tetrakis(methoxymethyl)glycoluril, 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

The brush forming composition may contain a surfactant. The surfactant is an additive for improving applicability onto a substrate.

As the surfactant, a known surfactant such as a nonionic surfactant or a fluorine-based surfactant can be used.

A content of the surfactant in the brush forming composition is, for example, 0.1 mass % to 5 mass % with respect to the brush polymer.

In the brush forming composition, when a component excluding a solvent is defined as a solid content, the solid content includes a brush polymer and an additive added as necessary.

A concentration of the solid content in the brush forming composition is not particularly limited, and is, for example, 0.1 mass % to 15 mass % and preferably 0.1 mass % to 10 mass %.

A preparation method of a brush forming composition is not particularly limited.

For example, a brush forming composition is obtained by dissolving a brush polymer and an additive added as necessary in an appropriate solvent. It is preferable that a brush polymer, and as necessary, an additive added are dissolved in the solvent, and then the resulting composition is filtered through a microfilter, and it is more preferable that the brush polymer and the additive are dissolved in the solvent, and then the resulting composition is filtered through a microfilter having a pore size of 0.2 μm or less.

In addition, a brush forming composition according to another embodiment of the present invention may be a composition (x) that is used in combination with the brush forming composition according to an embodiment of the present invention, is different from the brush forming composition according to an embodiment of the present invention, and has low adhesion to an underlayer film (x) for inducing self-assembly of a block copolymer of an upper layer. The low adhesion means that, for example, a thickness of the film attached to the underlayer film (x) evaluated by the method described in Examples is 20 nm or less, 10 nm or less, 5 nm or less, or 3 nm or less.

Conditions for film formation of underlayer film (x): Calcining is performed at 200 to 300° C. (for example, 240° C. or 250° C.) for 0.5 to 3 minutes (for example, 1 minute).

The composition (x) is an underlayer film forming composition (x) which is used to cause phase separation of a layer containing a block copolymer formed on a substrate and is described in WO 2018/135455 A, in which the composition is a copolymer represented by the following formula:
the copolymer having:
a unit structure (A) derived from a styrene compound containing a tert-butyl group;
a unit structure (B) derived from an aromatic-containing vinyl compound not containing a hydroxy group, the unit structure being other than the (A) above;
a unit structure (C) derived from a compound containing a (meth)acryloyl group and not containing a hydroxy group; and
a unit structure (D) derived from a crosslink forming group-containing compound,
copolymerization ratios with respect to the entire copolymer are (A) 25 to 90 mol %, (B) 0 to 65 mol %, (C) 0 to 65 mol %, and (D) 10 to 20 mol %, and
a unit structure containing an aromatic group is 81 to 90 mol % in (A)+(B)+(C).

The unit structure (A) derived from a styrene compound containing a tert-butyl group may be a composition (x) represented by Formula (1).

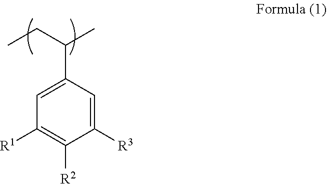

(In Formula (1), one or two of R¹ to R³ are tert-butyl groups.)

The unit structure (D) derived from a crosslink forming group-containing compound may be a unit structure represented by Formula (2-1), (2-2), (3-1), or (3-2).

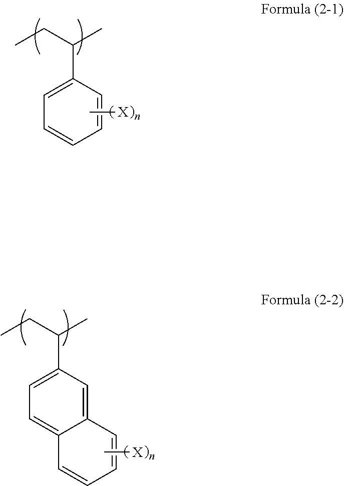

(In Formulas (2-1) and (2-2), n X's each independently represent a hydroxy group, a halogen atom, an alkyl group, an alkoxy group, a cyano group, an amide group, an alkoxycarbonyl group, or a thioalkyl group, and n represents an integer of 1 to 7.)

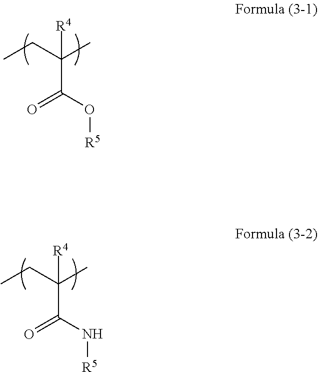

(In Formulas (3-1) and (3-2), R⁴ represents a hydrogen atom or a methyl group, and R⁵ represents a linear, branched, or cyclic alkyl group having 1 to 10 carbon atoms which has a hydroxy group and may be substituted with a halogen atom, or a hydroxyphenyl group.)

In the unit structure derived from an aromatic group-containing vinyl compound not containing a hydroxy group, the unit structure (B) other than the (A) above may be a unit structure represented by Formula (4-1) or (4-2).

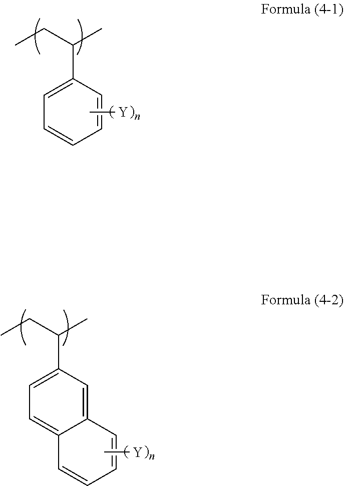

(In Formulas (4-1) and (4-2), n Y's each independently represent a halogen atom, an alkyl group, an alkoxy group, a cyano group, an amide group, an alkoxycarbonyl group, or a thioalkyl group, and n represents an integer of 0 to 7.)

The unit structure (C) derived from a compound containing a (meth)acryloyl group and not containing a hydroxy group may be a unit structure represented by Formula (5-1) or (5-2).

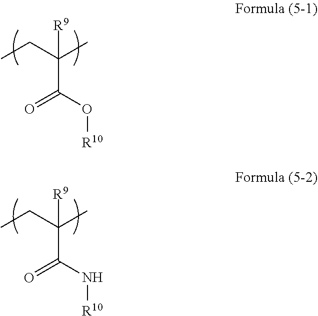

(In Formulas (5-1) and (5-2), R⁹ represents a hydrogen atom or a methyl group, and R¹⁰'s each independently represent a hydrogen atom, an alkoxy group having 1 to 5 carbon atoms, a linear, branched or cyclic alkyl group having 1 to 10 carbon atoms which may be substituted with a halogen atom, a benzyl group, or an anthrylmethyl group.)

The contents of WO 2018/135455 A are hereby incorporated in their entireties by reference, to the extent that they have been disclosed herein.

In addition, the composition (x) may contain a polymer (X-1) having a unit structure derived from an aromatic compound as described in WO 2022/039187 A.

The aromatic compound preferably contains an aryl group having 6 to 40 carbon atoms.

Examples of the aryl group having 6 to 40 carbon atoms include a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-fluorophenyl group, an o-methoxyphenyl group, a p-methoxyphenyl group, a p-nitrophenyl group, a p-cyanophenyl group, an α-naphthyl group, a β-naphthyl group, an o-biphenylyl group, an m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group. Among them, the aromatic compound preferably contains a phenyl group, an α-naphthyl group (=1-naphthyl group), or a β-naphthyl group (=2-naphthyl group).

It is preferable that the α-naphthyl group (=1-naphthyl group) or the β-naphthyl group (=2-naphthyl group) is contained in an amount of 40 mol % or more, 45 mol % or more, 50 mol % or more, 60 mol % or more, 70 mol % or more, or 80 mol % or more, with respect to the entire polymer (X-1). An upper limit is, for example, 95 mol % or 90 mol %.

The polymer (X-1) may be, for example, a polymer derived from 1-vinylnaphthalene, 2-vinylnaphthalene, or benzyl methacrylate. Preferably, the polymer (X-1) may be a polymer derived from 2-vinylnaphthalene or benzyl methacrylate.

The polymer (X-1) preferably contains 50 mol % or more of the unit structure derived from an aromatic compound with respect to the entire unit structure of the polymer (X-1). The polymer (X-1) further preferably contains, for example, 50 mol % to 99 mol %, 55 mol % to 99 mol %, 60 mol % to 99 mol %, 65 mol % to 99 mol %, 70 mol % to 99 mol %, 75 mol % to 99 mol %, 80 mol % to 99 mol %, 81 mol % to 99 mol %, 82 mol % to 98 mol %, 83 mol % to 97 mol %, 84 mol % to 96 mol %, and 85 mol % to 95 mol % of the unit structure derived from an aromatic compound with respect to the entire unit structure of the polymer (X-1).

In addition, the composition (x) may be an underlayer film forming composition of a self-assembled film, the composition containing a polymer (X-2) having a unit structure of a polycyclic aromatic vinyl compound in an amount of 0.2 mol % or more with respect to the entire unit structure of the polymer as described in WO 2014/097993 A.

The polymer (X-2) may be a polymer (X-2) having a unit structure of an aromatic vinyl compound in an amount of 20 mol % or more with respect to the entire unit structure of the polymer (X-2) and having a unit structure of a polycyclic aromatic vinyl compound in an amount of 1 mol % or more with respect to the entire unit structure of the aromatic vinyl compound.

The aromatic vinyl compound may contain vinylnaphthalene, acenaphthylene, or vinylcarbazole, each of which may be substituted, and the polycyclic aromatic vinyl compound may be vinylnaphthalene, acenaphthylene, or vinylcarbazole.

The aromatic vinyl compound may contain styrene which may be substituted, and vinylnaphthalene, acenaphthylene, or vinylcarbazole, each of which may be substituted, and the polycyclic aromatic vinyl compound may be vinylnaphthalene, acenaphthylene, or vinylcarbazole.

The aromatic vinyl compound may contain styrene which may be substituted, and vinylnaphthalene, acenaphthylene, or vinylcarbazole, each of which may be substituted, and the polycyclic aromatic vinyl compound may be vinylnaphthalene, acenaphthylene, or vinylcarbazole, each of which may be substituted.

The aromatic vinyl compound may be composed only of a polycyclic aromatic vinyl compound, and the aromatic vinyl compound may be vinylnaphthalene, acenaphthylene, or vinylcarbazole, each of which may be substituted.

The polymer (X-2) may have 60 to 95 mol % of a unit structure of an aromatic vinyl compound with respect to the entire unit structure of the polymer (X-2).

The polymer (X-2) may further have a unit structure having a crosslink forming group.

The crosslink forming group may be a hydroxy group, an epoxy group, a protected hydroxy group, or a protected carboxyl group.

Specific examples of the polymer (X-2) are shown below.

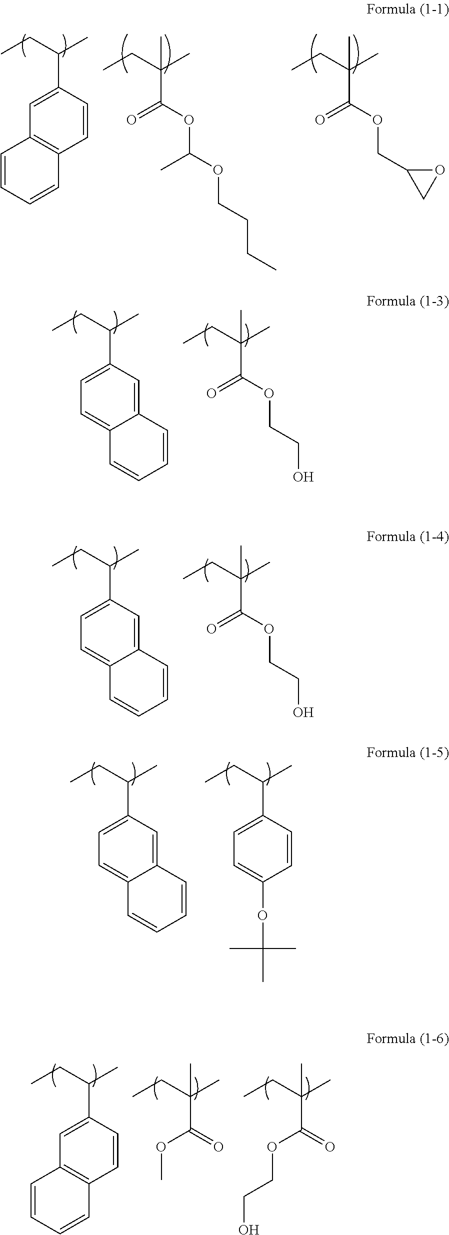

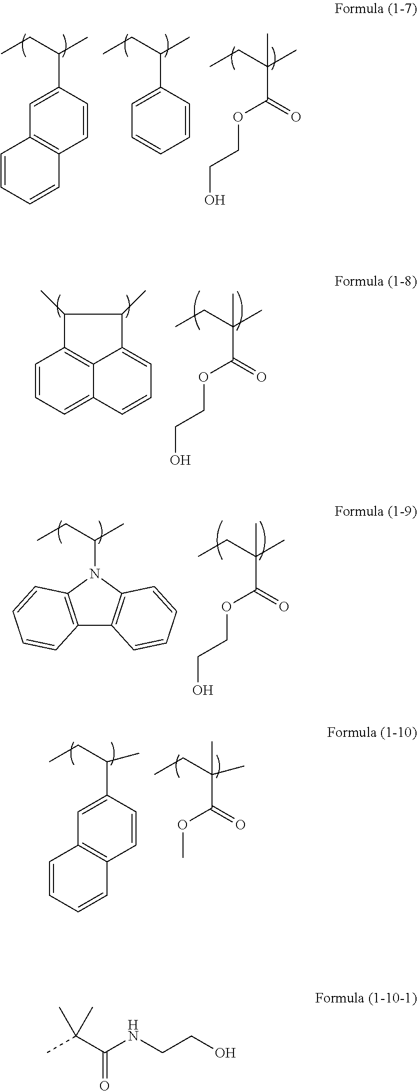

(The structure of Formula (1-10-1) is an example of a polymer terminal structure of Formula (1-10).)

The contents of WO 2014/097993 A are hereby incorporated in their entireties by reference, to the extent that they have been disclosed herein.

(Substrate with Underlayer Film)

A substrate with an underlayer film of the present invention is obtained by exposing, to a solvent, a precursor film of an underlayer film obtained by applying the brush forming composition of the present invention onto a substrate and heating the brush forming composition.

Examples of a production method of the substrate with an underlayer film include the following step (1).

### (Production Method of Substrate Having Phase-Separated Pattern of Block Copolymer)

A production method of a substrate having a phase-separated pattern of a block copolymer of the present invention includes the following steps (1) to (3).
Step (1): Step of forming an underlayer film on a substrate using the brush forming composition of the present invention
Step (2): Step of forming a layer containing a block copolymer on the underlayer film
Step (3): Step of subjecting the block copolymer to phase separation

Furthermore, the production method of the substrate having a phase-separated pattern of a block copolymer preferably includes a step of forming an upper layer film on a layer containing the block copolymer between the steps (2) and (3).

### <Step (1)>

The step (1) is a step of forming an underlayer film on a substrate using the brush forming composition of the present invention.

In order to obtain neutral surface energy, an underlayer film is formed on the substrate.

The substrate is formed of, for example, a base material selected from the group consisting of silicon, silicon oxide, glass, surface-modified glass, plastic, ceramic, a transparent base material, a flexible base material, a base material used in roll-to-roll processing, and a combination thereof. A silicon wafer, quartz, glass, or plastic is preferable, and a silicon wafer is more preferable.

The substrate is typically a silicon wafer, but a silicon on insulator (SOI) substrate or a compound semiconductor wafer such as gallium arsenide (GaAs), indium phosphide (InP), or gallium phosphide (GaP) may be used. A substrate on which an insulating film such as a silicon nitride film, a silicon oxide film, a nitrogen-containing silicon oxide film (SiON film), or a carbon-containing silicon oxide film (SiOC film) is formed may be used, and in this case, the brush forming composition according to the present invention is applied onto the insulating film.

In addition, the substrate before the underlayer film is formed using the brush forming composition may include a silicon and organic group-containing film. The silicon and organic group-containing film is a film formed using a hydrolysis condensate of a hydrolyzable silane having an organic group (also referred to as an organosilicon compound). The silicon and organic group-containing film contains, for example, a hydrolysis condensate of a hydrolyzable silane containing a compound represented by the following Formula (A).

R^{a}ₓSi(R^{b})₄₋ₓ (A)

(In Formula (A), R^{a} represents an alkyl group, an aryl group, a halogenated alkyl group, a halogenated aryl group, an alkoxyaryl group, an alkenyl group, an organic group having an epoxy group, an organic group having an acryloyl group, an organic group having a methacryloyl group, an organic group having a mercapto group, or an organic group having a cyano group, R^{b} represents an alkoxy group, an acyloxy group, or a halogen atom, and x represents an integer of 0 to 3.)

The silicon and organic group-containing film can be formed of, for example, a silicon-containing resist underlayer film forming composition. Examples of such a silicon-containing resist underlayer film forming composition include silicon-containing resist underlayer film forming compositions described below.

JP 2020-076999 A, WO 2019/181873 A, WO 2019/082934 A, WO 2019/009413 A, WO 2018/181989 A, WO 2018/079599 A, WO 2016/080217 A, WO 2016/009965 A, WO 2016/009939 A, WO 2015/194555 A, WO 2014/098076 A, WO 2014/069329 A, WO 2014/046055 A, WO 2013/191203 A, WO 2013/115032 A, WO 2013/022099 A, WO 2012/102261 A, WO 2012/053600 A, WO 2012/039337 A, WO 2011/105368 A, WO 2011/102470 A, WO 2011/033965 A, WO 2010/140551 A, WO 2010/071155 A, WO 2010/021290 A, WO 2009/104552 A, WO 2009/088039 A, WO 2009/069712 A

The step (1) preferably includes the following treatment (1-1) to treatment (1-3).
Treatment (1-1): Treatment in which a brush forming composition is applied onto a substrate
Treatment (1-2): Treatment in which the brush forming composition applied onto the substrate is heated to form a precursor film of an underlayer film
Treatment (1-3): Treatment in which the precursor film of the underlayer film is exposed to a solvent to obtain an underlayer film

A method for applying the brush forming composition onto the substrate in the treatment (1-1) can be a conventional method, and for example, the brush forming composition can be applied by an appropriate application method such as a spinner or a coater.

In the treatment (1-2), the brush forming composition applied onto the substrate is heated to form a precursor film of an underlayer film.

A heating temperature may be, for example, 80° C. to 500° C., 80° C. to 350° C., or 150° C. to 300° C.

A heating time may be, for example, 0.3 minutes to 60 minutes or 0.5 minutes to 2 minutes.

Preferably, the heating temperature is 150° C. to 300° C. and the heating time is 0.5 to 2 minutes.

In the treatment (1-2), for example, a functional group capable of binding to a substrate in the brush polymer binds to the substrate by heating.

A surface of the substrate usually has a functional group such as a hydroxyl group. For example, a surface of a silicon wafer has a —Si—OH group. A surface of the silicon and organic group-containing film has a —Si—OH group. In the treatment (1-2), for example, a functional group capable of binding to a substrate in the brush polymer binds to a functional group on the surface of the substrate by heating. As a result, a precursor film of an underlayer film is obtained on the substrate. The precursor film of the underlayer film has a polymer chain bonded to the substrate.

In the treatment (1-3), the precursor film of the underlayer film is exposed to a solvent to obtain an underlayer film.

The precursor film of the underlayer film has a polymer chain not bonded to the substrate. In the treatment (1-3), the precursor film of the underlayer film is exposed to a solvent, such that a polymer chain not bonded to the substrate is removed from the precursor film of the underlayer film, and the underlayer film is obtained. At this time, since the brush forming composition contains an organic base, a thick underlayer film is obtained as compared with a case where the composition does not contain an organic base.

The solvent to be used is not particularly limited, and examples thereof include a solvent used in the brush forming composition.

A method for exposing the precursor film of the underlayer film to a solvent is not particularly limited, and examples thereof include a method in which a substrate including the precursor film of the underlayer film is immersed in a solvent. An immersion time is not particularly limited.

A thickness of the underlayer film (underlayer film after exposure to a solvent) is not particularly limited, and is preferably 2.0 nm to 10.0 nm and more preferably 2.5 nm to 8.0 nm.

### <Step (2)>

The step (2) is a step of forming a layer containing a block copolymer on the underlayer film.

Hereinafter, the “layer containing a block copolymer” may be referred to as a “block copolymer layer”.

The block copolymer layer can be formed by a conventional method, for example, by applying a self-assembled film forming composition containing a block copolymer onto an underlayer film by means of spin coating or the like so as to have a predetermined film thickness, and baking the composition.

A baking (heating) temperature is not particularly limited, and may be, for example, 50° C. to 150° C., 70° C. to 130° C., or 80° C. to 120° C.

A baking time is not particularly limited, and may be, for example, 1 second to 10 minutes, 10 seconds to 5 minutes, or 30 seconds to 3 minutes.

A thickness of the layer containing the block copolymer to be formed is not particularly limited, and may be, for example, 5 nm to 200 nm, 10 nm to 130 nm, or 20 nm to 80 nm.

### <<Self-Assembled Film Forming Composition>>

A self-assembled film forming composition contains a block copolymer.

The self-assembled film forming composition usually contains a solvent.

The self-assembled film forming composition may have a solid content of 0.1 to 10 mass %, 0.1 to 5 mass %, or 0.1 to 3 mass %. The solid content is a remaining ratio obtained by removing the solvent from the film-forming composition.

A ratio of the block copolymer in the solid content can be 30 to 100 mass %, 50 to 100 mass %, 50 to 90 mass %, or 50 to 80 mass %.

The number of kinds of blocks present in the block copolymer can be 2 or 3 or more. The number of blocks present in the block copolymer can be 2 or 3 or more.

### <<<Block Copolymer>>>

Examples of the block polymer include combinations of AB, ABAB, ABA, and ABC.

As one of the methods for synthesizing the block copolymer, living radical polymerization and living cationic polymerization in which a polymerization process includes only an initiation reaction and a growth reaction and is not accompanied by a side reaction for deactivating a growth terminal can be used. The growth terminal can keep the growth active reaction during the polymerization reaction. By eliminating the occurrence of chain transfer, a polymer (PA) having a uniform length is obtained. By adding a different monomer (mb), the growth terminal of the polymer (PA) can be utilized to allow the polymerization of the monomer (mb) to proceed to form a block copolymer (AB).

For example, when there are two kinds of blocks PA and PB, a molar ratio of the polymer chain (PA) to the polymer chain (PB) can be 1:9 to 9:1 and preferably 3:7 to 7:3.

A volume ratio of the block copolymer is, for example, 30:70 to 70:30.

A homopolymer PA or PB is a polymer of a polymerizable compound having at least one radically polymerizable reactive group (vinyl group or vinyl group-containing organic group).

A weight average molecular weight Mw of the block copolymer is preferably 1,000 to 100,000 or 5,000 to 100,000. When the weight average molecular weight of the block copolymer is 1,000 or more, the applicability onto a base substrate is excellent, and when the weight average molecular weight of the block copolymer is 100,000 or less, the solubility in a solvent is excellent.

A polydispersity (Mw/Mn) of the block copolymer is preferably 1.00 to 1.50 and more preferably 1.00 to 1.20.

As the block copolymer used in the present invention, a known block copolymer can be used.

As a specific example of the block copolymer, a combination of a silicon-containing polymer chain and a non-silicon-containing polymer chain is preferable because a difference in dry etching rate can be increased.

Examples of the silicon-containing polymer chain include a silylated polystyrene derivative. Examples of the silylated polystyrene derivative include polysilanes (for example, polydihexylsilane and the like), polysiloxanes (for example, polydimethylsiloxane and the like), poly(trimethylsilylstyrene), and poly(pentamethyldisilylstyrene).

Particularly, the silylated polystyrene derivative is preferably poly(4-trimethylsilylstyrene) or poly(4-pentamethyldisilylstyrene) having a substituent at the 4-position.

A preferred example of the block copolymer is a block copolymer obtained by binding a silicon-free polymer having styrene as a structural unit which may be substituted with an organic group or a silicon-free polymer having a structure derived from lactide as a structural unit to a silicon-containing polymer having styrene substituted with a silicon-containing group as a structural unit.

Among them, a combination of a silylated polystyrene derivative and a polystyrene derivative, or a combination of a silylated polystyrene derivative and polylactide is preferable.

Among them, a combination of a silylated polystyrene derivative having a substituent at the 4-position and a polystyrene derivative having a substituent at the 4-position, or a combination of a silylated polystyrene derivative having a substituent at the 4-position and polylactide is preferable.

More preferred specific examples of the block copolymer include a combination of poly(trimethylsilylstyrene) and polymethoxystyrene, a combination of polystyrene and poly(trimethylsilylstyrene), and a combination of poly(trimethylsilylstyrene) and poly(D,L-lactide).

More preferred specific examples of the block copolymer include a combination of poly(4-trimethylsilylstyrene) and poly(4-methoxystyrene), a combination of polystyrene and poly(4-trimethylsilylstyrene), and a combination of poly(4-trimethylsilylstyrene) and poly(D,L-lactide).

Most preferred specific examples of the block copolymers include a poly(4-methoxystyrene)/poly(4-trimethylsilylstyrene) block copolymer and a polystyrene/poly(4-trimethylsilylstyrene) block copolymer.

The entire disclosure described in WO 2018/135456 A is incorporated herein by reference.

In addition, the block copolymer may be a block copolymer obtained by binding a silicon-free polymer to a silicon-containing polymer having styrene substituted with a silicon-containing group as a structural unit, and the silicon-free polymer may be a block copolymer having a unit structure represented by the following Formula (1-1c) or Formula (1-2c).

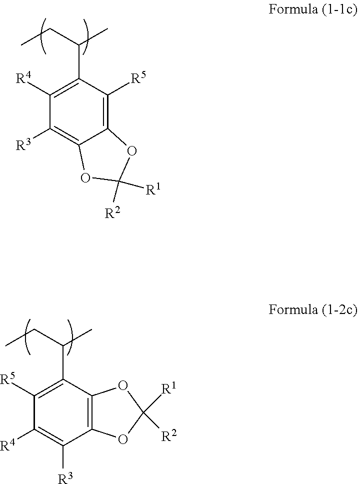

(In Formula (1-1c) or (1-2c), R¹ and R² each independently represent a hydrogen atom, a halogen atom, or an alkyl group having 1 to 10 carbon atoms, and R³ to R⁵ each independently represent a hydrogen atom, a hydroxy group, a halogen atom, an alkyl group having 1 to 10 carbon atoms, an alkoxy group having 1 to 10 carbon atoms, a cyano group, an amino group, an amide group, or a carbonyl group.)

The silicon-containing group may contain one silicon atom.

The silicon-containing polymer may have a unit structure represented by the following Formula (2c).

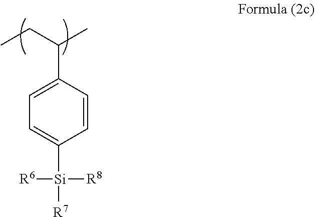

(In Formula (2c), R⁶ to R⁸ each independently represent an alkyl group having 1 to 10 carbon atoms or an aryl group having 6 to 40 carbon atoms.)

Furthermore, as the block copolymer, a block copolymer described in JP 2019-507815 A including the following
[BCP1] to [BCP4] may be used. The entire disclosure described in JP 2019-507815 A is incorporated herein by reference.
[BCP1]A block copolymer containing 5-vinylbenzo[d][1,3]dioxole.
[BCP2] The block copolymer according to [BCP1], in which the block copolymer further contains a block containing silicon.
[BCP3] The block copolymer according to [BCP2], in which the block copolymer further contains pentamethyldisilylstyrene.
[BCP4] The block copolymer according to [BCP3], in which the block copolymer is poly(5-vinylbenzo[d][1,3]dioxole)-b-poly(pentamethyldisilylstyrene).

The synthesis of poly(5-vinylbenzo[d][1,3]dioxole-block-4-pentamethyldisilylstyrene) as described above is shown in Scheme 1.

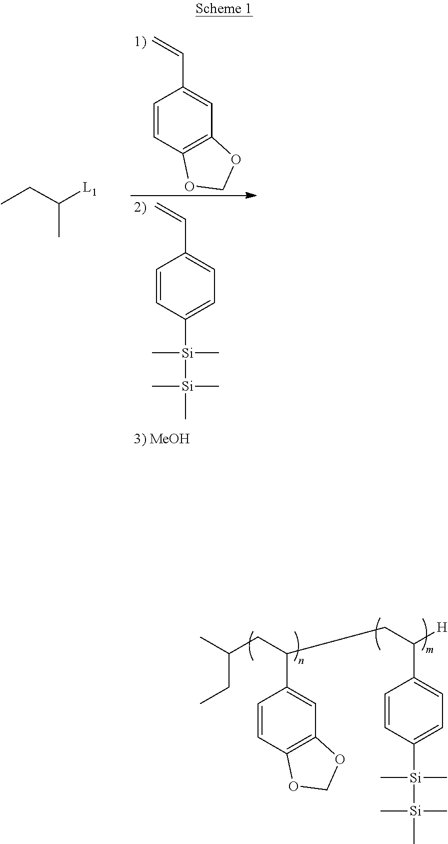

Me represents a methyl group.

Preferably, the silicon-containing polymer or the block containing silicon is poly(4-trimethylsilylstyrene) derived from 4-trimethylsilylstyrene. Preferably, the silicon-containing polymer or the block containing silicon is poly(pentamethyldisilylstyrene) derived from pentamethyldisilylstyrene. The aryl group having 6 to 40 carbon atoms means a monovalent group of a monocyclic or polycyclic aromatic hydrocarbon having 6 to 40 carbon atoms, and specific examples thereof include a phenyl group, a naphthyl group, and an anthryl group.

The entire disclosure described in WO 2020/017494 A is incorporated herein by reference.

In addition, a block copolymer composed of a combination of monomers described below may be used. Styrene, methyl methacrylate, dimethylsiloxane, propylene oxide, ethylene oxide, vinylpyridine, vinylnaphthalene, D,L-lactide, methoxystyrene, methylenedioxystyrene, trimethylsilylstyrene, and pentamethyldisilylstyrene.

A useful block copolymer contains at least two blocks and may be a copolymer such as a diblock, a triblock, or a tetrablock having separate blocks, each of which may be a homopolymer or a random or alternating copolymer.

Examples of a typical block copolymer include polystyrene-b-polyvinylpyridine, polystyrene-b-polybutadiene, polystyrene-b-polyisoprene, polystyrene-b-polymethylmethacrylate, polystyrene-b-polyalkenyl aromatic, polyisoprene-b-polyethylene oxide, polystyrene-b-poly(ethylene-propylene), polyethylene oxide-b-polycaprolactone, polybutadiene-b-polyethylene oxide, polystyrene-b-poly(t-butyl (meth)acrylate), polymethyl methacrylate-b-poly(t-butyl methacrylate), polyethylene oxide-b-polypropylene oxide, polystyrene-b-polytetrahydrofuran, polystyrene-b-polyisoprene-b-polyethylene oxide, poly(styrene-b-dimethylsiloxane), poly(methyl methacrylate-b-dimethylsiloxane), poly(methyl (meth)acrylate-r-styrene)-b-polymethyl methacrylate, poly(methyl (meth)acrylate-r-styrene)-b-polystyrene, poly(p-hydroxystyrene-r-styrene)-b-polymethyl methacrylate, poly(p-hydroxystyrene-r-styrene)-b-polyethylene oxide, polyisoprene-b-polystyrene-b-polyferrocenylsilane, and a combination including at least one kind of the block copolymers described above.

In addition, examples of the block copolymer include a block copolymer composed of a combination of organic polymers and/or metal-containing polymers as described below.

A typical organic polymer includes poly(9,9-bis(6′-N,N,N-trimethylammonium)-hexyl)-fluorenphenylene (PEP), poly(4-vinylpyridine) (4PVP), hydroxypropylmethylcellulose (HPMC), polyethylene glycol (PEG), a poly(ethylene oxide)-poly(propylene oxide) diblock or multiblock copolymer, polyvinyl alcohol (PVA), poly(ethylene-vinyl alcohol) (PEVA), polyacrylic acid (PAA), polylactic acid (PLA), poly(ethyloxazoline), poly(alkyl acrylate), polyacrylamide, poly(N-alkylacrylamide), poly(N,N-dialkylacrylamide), polypropylene glycol (PPG), polypropylene oxide (PPO), partially or entirely hydrogenated poly(vinyl alcohol), dextran, polystyrene (PS), polyethylene (PE), polypropylene (PP), polyisoprene (PI), polychloroprene (CR), polyvinyl ether (PVE), polyvinyl acetate (PVA), polyvinyl chloride (PVC), polyurethane (PU), a polyacrylate, a polymethacrylate, oligosaccharides, or polysaccharides, but is not limited thereto.

Examples of the metal-containing polymer include, but are not limited to, a silicon-containing polymer, such as polydimethylsiloxane (PDMS), cage-type silsesquioxane (POSS), or poly(trimethylsilystyrene) (PTMSS)-, or a polymer containing silicon and iron, such as poly(ferrocenyldimethylsilane) (PFS).

Examples of a typical block copolymer (copolymer) include, but are not limited to, a diblock copolymer such as polystyrene-b-polydimethylsiloxane (PS-PDMS), poly(2-vinylpropylene)-b-polydimethylsiloxane (P2VP-PDMS), polystyrene-b-poly(ferrocenyldimethylsilane) (PS-PFS), or polystyrene-b-poly-DL lactic acid (PS-PLA)-, or a triblock copolymer such as polystyrene-b-poly(ferrocenyldimethylsilane)-b-poly(2-vinylpyridine) (PS-PFS-P2VP), polyisoprene-b-polystyrene-b-poly(ferrocenyldimethylsilane) (PI-PS-PFS), or polystyrene-b-poly(ferrocenyldimethylsilane)-b-polystyrene (PS-PTMSS-PS)—. In one example, the PS-PTMSS-PS block copolymer includes a poly(trimethylsilystyrene) polymer block constituted by two chains of PTMSS connected by a linker having four styrene units. Modifications of the block copolymer as disclosed, for example, in US 2012/0046415 A, are also conceivable.

Examples of the other block copolymers include a block copolymer in which a polymer having styrene or a derivative thereof as a structural unit is bonded to a polymer having a (meth)acrylic acid ester as a structural unit, a block copolymer in which a polymer having styrene or a derivative thereof as a structural unit is bonded to a polymer having siloxane or a derivative thereof as a structural unit, and a block copolymer in which a polymer having alkylene oxide as a structural unit is bonded to a polymer having a (meth)acrylic acid ester as a structural unit. Note that the “(meth)acrylic acid ester” means one or both of an acrylic acid ester having a hydrogen atom bonded to the α-position and a methacrylic acid ester having a methyl group bonded to the α-position.

Examples of the (meth)acrylic acid ester include those in which a substituent such as an alkyl group or a hydroxyalkyl group is bonded to a carbon atom of (meth)acrylic acid. Examples of the alkyl group used as the substituent include a linear, branched, or cyclic alkyl group having 1 to 10 carbon atoms. Specific examples of the (meth)acrylic acid ester include methyl (meth)acrylate, ethyl (meth)acrylate, propyl (meth)acrylate, cyclohexyl (meth)acrylate, octyl (meth)acrylate, nonyl (meth)acrylate, hydroxyethyl (meth)acrylate, hydroxypropyl (meth)acrylate, benzyl (meth)acrylate, anthracene (meth)acrylate, glycidyl (meth)acrylate, 3,4-epoxycyclohexylmethane (meth)acrylate, and propyltrimethoxysilane (meth)acrylate.

Examples of the derivative of styrene include α-methylstyrene, 2-methylstyrene, 3-methylstyrene, 4-methylstyrene, 4-t-butylstyrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, vinylcyclohexane, 4-vinylbenzyl chloride, 1-vinylnaphthalene, 4-vinylbiphenyl, 1-vinyl-2-pyrrolidone, 9-vinylanthracene, and vinylpyridine.

Examples of the derivative of siloxane include dimethylsiloxane, diethylsiloxane, diphenylsiloxane, and methylphenylsiloxane.

Examples of the alkylene oxide include ethylene oxide, propylene oxide, isopropylene oxide, and butylene oxide.

Examples of the block copolymer include a styrene-polyethyl methacrylate block copolymer, a styrene-(poly-t-butyl methacrylate) block copolymer, a styrene-polymethacrylic acid block copolymer, a styrene-polymethyl acrylate block copolymer, a styrene-polyethyl acrylate block copolymer, a styrene-(poly-t-butyl acrylate) block copolymer, and a styrene-polyacrylic acid block copolymer.

The entire disclosure described in WO 2022/039187 A is incorporated herein by reference.

### <<<Solvent>>>

Examples of the solvent used in the self-assembled film forming composition include the following organic solvents.
Aliphatic hydrocarbon-based solvents such as n-pentane, i-pentane, n-hexane, i-hexane, n-heptane, i-heptane, 2,2,4-trimethylpentane, n-octane, i-octane, cyclohexane, and methylcyclohexane
Aromatic hydrocarbon-based solvents such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, and trimethylbenzene
Monoalcohol-based solvents such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol
Polyhydric alcohol-based solvents such as ethylene glycol, propylene glycol, 1,3-butylene glycol, pentanediol-2,4, 2-methylpentanediol-2,4, hexanediol-2,5, heptanediol-2,4, 2-ethylhexanediol-1,3, diethylene glycol, dipropylene glycol, triethylene glycol, tripropylene glycol, and glycerin
Ketone-based solvents such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone
Ether-based solvents such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran
Ester-based solvents such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate
Nitrogen-containing solvents such as N-methylformamide, N,N-dimethylformamide, N,N-diethylformamide, acetamide, N-methylacetamide, N,N-dimethylacetamide, N-methylpropionamide, and N-methylpyrrolidone
Sulfur-containing solvents such as dimethyl sulfide, diethyl sulfide, thiophene, tetrahydrothiophene, dimethyl sulfoxide, sulfolane, and 1,3-propane sultone

In particular, propylene glycol monomethyl ether, propylene glycol monoethyl ether, propylene glycol monopropyl ether, propylene glycol monobutyl ether, propylene glycol dimethyl ether, propylene glycol diethyl ether, propylene glycol monomethyl ether acetate, propylene glycol monoethyl ether acetate, and propylene glycol monopropyl ether acetate are preferable from the viewpoint of the storage stability of the solution of the composition.

In addition, the solvent contained in the self-assembled film forming composition may be a combination of a low-boiling-point solvent (A) having a boiling point of 160° C. or lower and a high-boiling-point solvent (B) having a boiling point of 170° C. or higher as described in WO 2018/135456 A.

As the low-boiling-point solvent (A) having a boiling point of 160° C. or lower, for example, propylene glycol monomethyl ether acetate (boiling point: 146° C.), n-butyl acetate (boiling point: 126° C.), and methyl isobutyl ketone (boiling point: 116° C.) are preferable.

As the high-boiling-point solvent (B) having a boiling point of 170° C. or higher, for example, N-methylpyrrolidone (boiling point: 204° C.), diethylene glycol monomethyl ether (boiling point: 193° C.), N,N-dimethylisobutyramide (boiling point: 175° C.), 3-methoxy-N,N-dimethylpropanamide (boiling point: 215° C.), and γ-butyrolactone (boiling point: 204° C.) are preferable.

Two or more kinds of each of the low-boiling-point solvent (A) and the high-boiling-point solvent (B) can be selected and mixed for use.

As a preferred aspect, the high-boiling-point solvent (B) is contained in an amount of 0.3 to 2.0 wt % with respect to the total amount of the solvent contained in the composition. Most preferably, the high-boiling-point solvent (B) is contained in an amount of 0.5 to 1.5 wt %.

The entire disclosure described in WO 2018/135456 A is incorporated herein by reference.

### <Step of Forming Upper Layer Film>

The step of forming an upper layer film is a step of forming an upper layer film on the layer containing the block copolymer between the step (2) and the step (3).

Optionally, an upper layer film is formed on the block copolymer layer obtained above. The formation of the upper layer film can be performed by a well-known method, that is, by applying an upper layer film forming composition onto the block copolymer layer and baking the composition.

The upper layer film forming composition is applied onto the block copolymer layer by conventional means such as spin coating to form an upper layer film.

A formation film thickness of the upper layer film is not particularly limited, and is generally 3 nm to 100 nm, preferably 10 nm to 70 nm, and particularly preferably 20 nm to 60 nm. The upper layer film forming composition is preferably dissolved in a solvent or a solvent mixture that does not damage the block copolymer, does not dissolve the block copolymer, and does not substantially swell the block copolymer.

### <<Upper Layer Film Forming Composition>>

The upper layer film forming composition is a composition used to cause phase separation of a block copolymer of a layer containing a block copolymer.

The upper layer film forming composition contains, for example, the following components (X) and (Y).
Component (X): Copolymer (x) containing a structural unit derived from a maleimide structure and a structural unit derived from a styrene structure
Component (Y): Ether compound having 8 to 16 carbon atoms as a solvent

The upper layer film formed of the upper layer film forming composition may be formed on the block copolymer layer, and may be removed after the orientation of the block copolymer is controlled by heating. Even for a block copolymer layer that cannot be oriented only by heating, orientation can be achieved by using an upper layer film formed by the present composition.

### <<<Component (X): Copolymer (X)>>>

The component (X) is a copolymer (X).

The copolymer (X) contains a structural unit derived from a maleimide structure and a structural unit derived from a styrene structure.

In the present specification, the “maleimide structure” and the “styrene structure” refer to chemical structures having maleimide and styrene as skeletons, respectively. The “structural unit derived from” refers to a repeating unit forming a main chain of a copolymer derived from a compound having a maleimide structure or a styrene structure while maintaining the skeleton thereof.

<<<<(x) Structural Unit Derived from Maleimide Structure and Structural Unit Derived from Styrene Structure>>>>

Preferably, the structural unit derived from a maleimide structure is represented by Formula (11).

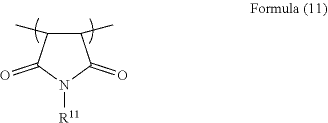

(In Formula (11), R¹¹ represents a hydrogen atom, a linear, branched, or cyclic alkyl group having 1 to 10 carbon atoms, or an aryl group having 6 to 10 carbon atoms which may be substituted with a halogen atom.)

Preferably, the structural unit derived from a styrene structure is represented by Formula (12).

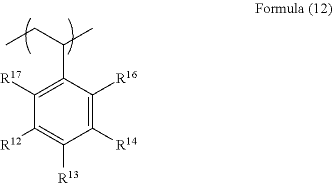

(In Formula (12), R¹² to R¹⁴ and R¹⁷ and R¹⁸ each independently represent a hydrogen atom, an alkoxy group having 1 to 5 carbon atoms, or a linear, branched, or cyclic alkyl group having 1 to 10 carbon atoms which may be substituted with a halogen atom.)

R¹⁷ and R¹⁸ are preferably hydrogen atoms.

It is desirable that molar ratios of the structural units represented by Formulas (11) and (12) to the entire copolymer (X) are
30 to 70 mol % of the structural unit of Formula (11), and
20 to 50 mol % of the structural unit of Formula (12), respectively.
   <<<<Structural Unit (y) Derived from (Meth)Acrylic Group>>>>

Furthermore, the copolymer (X) may contain a structural unit (y) derived from a (meth)acrylic group in addition to Formulas (11) and (12).

Preferably, the structural unit derived from a (meth)acrylic group is represented by Formula (13).

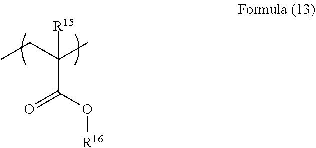

(In Formula (13), R¹⁵ and R¹⁶ each independently represent a hydrogen atom, an alkoxy group having 1 to 5 carbon atoms, or a linear, branched, or cyclic alkyl group having 1 to 10 carbon atoms which may be substituted with a halogen atom.)

A molar ratio of the structural unit of Formula (13) to the entire copolymer (X) is preferably 0.1 to 50 mol %, more preferably 0.1 to 30 mol %, still more preferably 0.1 to 20 mol %, and most preferably 0.1 to 10 mol %, with respect to the entire copolymer (X)

In Formula (11), examples of the aryl group having 6 to 10 carbon atoms include a phenyl group, a benzyl group, and a naphthyl group.

A distribution of the structural units represented by Formulas (11), (12), and (13) in the copolymer (X) is not particularly limited. That is, in the copolymer (X), the structural units represented by Formulas (11) and (12) may be alternately copolymerized or randomly copolymerized. In addition, when the structural unit represented by Formula (13) coexists, the structural units represented by Formulas (11), (12), and (13) in the copolymer (X) may each constitute a block or may be randomly bonded.

The number of repetitions of the structural units represented by Formulas (11), (12), and (13) in the copolymer (X) can be appropriately selected within a range of mol % of each of the structural units described above, and a weight average molecular weight Mw of the copolymer (X) is 5,000 to 500,000 and preferably 10,000 to 100,000.

### <<<<Production Method of Copolymer (X)>>>>

A production method of the copolymer (X) includes, for example, a step of copolymerizing a monomer mixture containing a compound represented by Formula (14) and a compound represented by Formula (15).

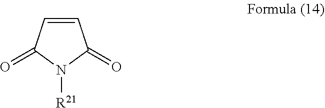

(In Formula (14), R²¹ represents a hydrogen atom, a linear, branched, or cyclic alkyl group having 1 to 10 carbon atoms, or an aryl group having 6 to 10 carbon atoms which may be substituted with a halogen atom.)

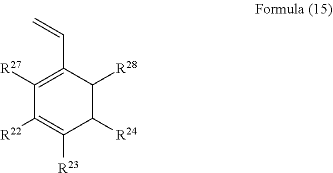

(In Formula (15), R²² to R²⁴ and R²⁷ and R²⁸ each independently represent a hydrogen atom, an alkoxy group having 1 to 5 carbon atoms, or a linear, branched, or cyclic alkyl group having 1 to 10 carbon atoms which may be substituted with a halogen atom.)

R²⁷ and R²⁸ are preferably hydrogen atoms.

The monomer mixture can optionally contain a compound represented by Formula (16).

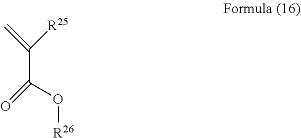

(In Formula (16), R⁵ and R²⁶ each independently represent a hydrogen atom, an alkoxy group having 1 to 5 carbon atoms, or a linear, branched, or cyclic alkyl group having 1 to 10 carbon atoms which may be substituted with a halogen atom.)

The monomer mixture preferably contains
compounds represented by Formulas (14) and (15) in ratios of
30 to 70 mol % of the compound represented by Formula (14), and
20 to 50 mol % of the compound represented by Formula (15), with respect to the monomer mixture.

When the monomer mixture contains a compound represented by Formula (16), the monomer mixture preferably contains, in terms of ratio,
30 to 70 mol % of the compound represented by Formula (14),
20 to 50 mol % of the compound represented by Formula (15), and
0.1 to 40 mol % of the compound represented by Formula (16), with respect to the monomer mixture.

Specific examples of the compound represented by Formula (14) include the following.

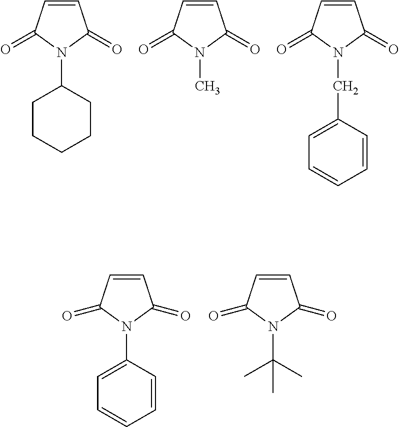

Specific examples of the compound represented by Formula (15) include the following.

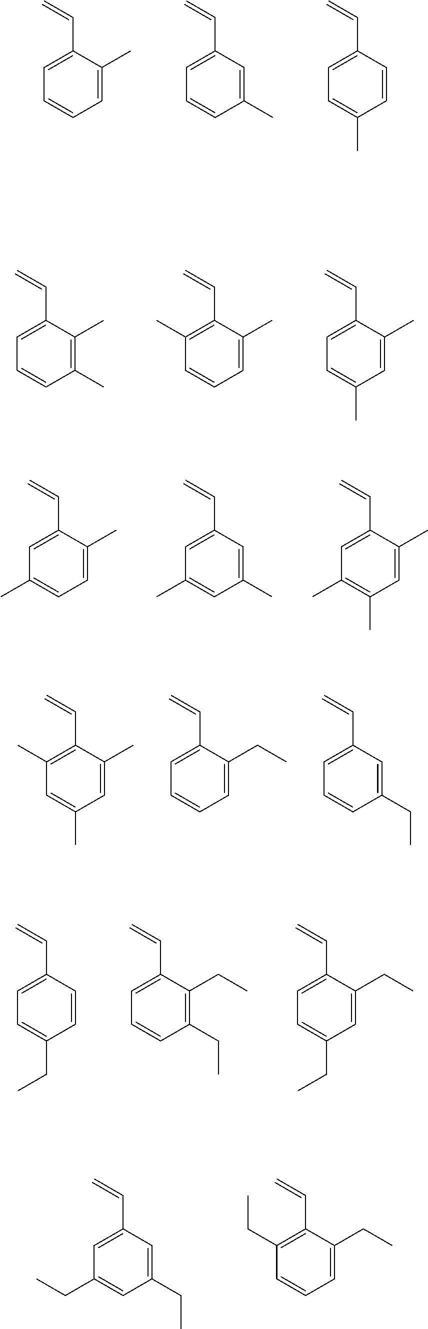

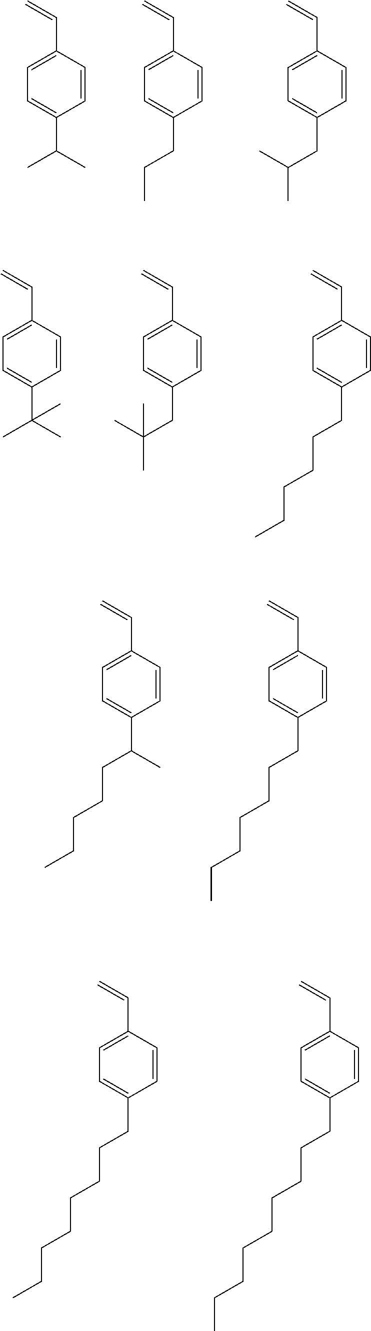

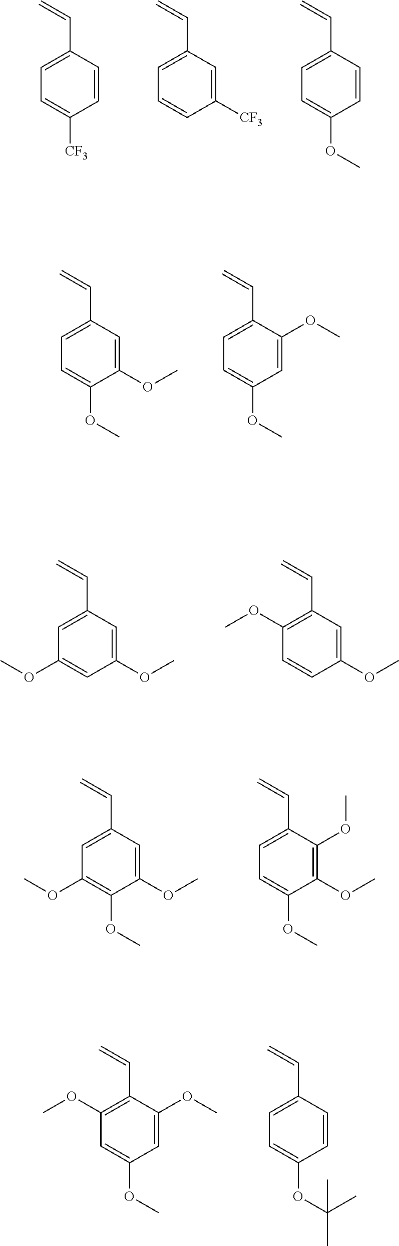

The copolymer (X) can be obtained by a known polymerization method. Examples of the known polymerization method include radical polymerization, anionic polymerization, and cationic polymerization. Various known techniques such as solution polymerization, suspension polymerization, emulsion polymerization, and bulk polymerization can be used.

Examples of the polymerization initiator used during polymerization include 2,2′-azobis(isobutyronitrile), 2,2′-azobis(2-methylbutyronitrile), 2,2′-azobis(2,4-dimethylvaleronitrile), 4,4′-azobis(4-cyanovaleric acid), 2,2′-azobis(2,4-dimethylvaleronitrile), 2,2′-azobis(4-methoxy-2,4-dimethylvaleronitrile), 2,2′-azobis(isobutyronitrile), 1,1′-azobis(cyclohexane-1-carbonitrile), 1-[(1-cyano-1-methylethyl)azo]formamide, 2,2′-azobis[2-(2-imidazolin-2-yl)propane]dihydrochloride, 2,2′-azobis[2-(2-imidazolin-2-yl)propane], and 2,2′-azobis(2-methylpropionamidine)dihydrochloride.

Examples of the solvent used during polymerization include dioxane, ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate. These solvents may be used alone or in combination.

The reaction condition is 50° C. to 200° C., and the mixture is stirred for 1 hour to 48 hours to obtain the copolymer (X) suitable for implementing the present invention.

The solution containing the copolymer (X) obtained as described above can also be used as it is for preparing an upper layer film forming composition. In addition, the copolymer (X) may be precipitated and isolated in a poor solvent such as methanol, ethanol, isopropanol, or water, or a mixed solvent thereof, and recovered and used.

After the copolymer (X) is isolated, the copolymer (X) may be used by being redissolved in the following ether compound having 8 to 16 carbon atoms as it is, or may be used after being dried. The drying condition in the case of drying is desirably 30 to 100° C. for 6 to 48 hours in an oven or the like. After recovering the copolymer (X), the copolymer (X) is redissolved in the following ether compound having 8 to 16 carbon atoms to prepare a composition suitable for implementing the present invention, and the composition can be used as an upper layer film forming composition.

### <<<Component (Y): Solvent>>>

The solvent used in the upper layer film forming composition is an ether compound having 8 to 16 carbon atoms. More specifically, the ether compound having 8 to 16 carbon atoms (hereinafter, may be referred to as an “ether-based solvent”) used as a solvent in the upper layer film forming composition is represented by the following Formula (6).

A₁-O-A₂ Formula (6)

In Formula (6), A₁ and A₂ each independently represent a linear, branched, or cyclic saturated alkyl group having 1 to 15 carbon atoms which may be substituted.

Among them, preferred solvents include dibutyl ether, diisobutyl ether, di-tert-butyl ether, dipentyl ether, diisoamyl ether, dihexyl ether, dioctyl ether, and cyclopentyl methyl ether, which are excellent in a balance between the solubility of the copolymer (X) and the insolubility of the block copolymer suitable for implementing the present invention, further preferred solvents include dibutyl ether, diisobutyl ether, and diisoamyl ether, and particularly preferred solvents include diisoamyl ether. These ether-based solvents can be used alone or as a mixture.

In addition, for example, for the convenience of synthesis of the copolymer (X), the following organic solvent may be mixed together with an ether solvent. The solvent is, for example, the solvent described in the section of the production method of the copolymer (X). The solvent other than the ether-based solvent may be present in a ratio of 0.01 to 13 mass % with respect to the ether-based solvent.

### <<<Additive>>>

The upper layer film forming composition can further contain additives such as a surfactant and a rheology modifier.

The rheology modifier is added mainly for the purpose of improving the fluidity of the upper layer film forming composition. Specific examples thereof include the following.
Phthalic acid derivatives such as dimethyl phthalate, diethyl phthalate, diisobutyl phthalate, dihexyl phthalate, and butyl isodecyl phthalate
Adipic acid derivatives such as di-n-butyl adipate, diisobutyl adipate, diisooctyl adipate, and octyl decyl adipate
Maleic acid derivatives such as di-n-butyl maleate, diethyl maleate, and dinonyl maleate
Oleic acid derivatives such as methyl oleate, butyl oleate, and tetrahydrofurfuryl oleate
Stearic acid derivatives such as n-butyl stearate and glyceryl stearate

These rheology modifiers are usually blended in a ratio of less than 30 mass % with respect to 100 mass % of the entire upper layer film forming composition.

In the upper layer film forming composition, a surfactant can be blended in order to further improve the applicability for surface unevenness without generating pinholes, striations, and the like.

Examples of the surfactant include the following.
Nonionic surfactant
   Polyoxyethylene alkyl ethers such as polyoxyethylene lauryl ether, polyoxyethylene stearyl ether, polyoxyethylene cetyl ether, and polyoxyethylene oleyl ether
   Polyoxyethylene alkyl aryl ethers such as polyoxyethylene octyl phenol ether and polyoxyethylene nonyl phenol ether
   Polyoxyethylene-polyoxypropylene block copolymers
   Sorbitan fatty acid esters such as sorbitan monolaurate, sorbitan monopalmitate, sorbitan monostearate, sorbitan monooleate, sorbitan trioleate, and sorbitan tristearate
   Polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate
Fluorine-based surfactants such as Eftop EF301, EF303, and EF352 (manufactured by Tohkem Products Corporation), Megafac F171 and F173 (manufactured by Dainippon Ink and Chemicals, Inc.), Fluorad FC430 and FC431 (manufactured by Sumitomo 3M Ltd.), Asahiguard AG710, Surflon S-382, SC101, SC102, SC103, SC104, SC105, and SC106 (manufactured by AGC Inc.), and FTERGENT series (manufactured by Neos Corporation)
Organosiloxane polymer KP341 (manufactured by Shin-Etsu Chemical Co., Ltd.)

A blending amount of these surfactants is usually 0.2 mass % or less, and preferably 0.1 mass % or less, with respect to 100 mass % of the entire upper layer film forming composition. These surfactants may be added alone, or may be added in combination of two or more kinds thereof.

A content of the copolymer (X) in the solid content in the upper layer film forming composition is preferably 20 mass % or more, for example, 20 to 100 mass % or 30 to 100 mass %. The solid content of the upper layer film forming composition is preferably 0.1 to 50 mass % and more preferably 0.3 to 30 mass %. Here, the solid content is obtained by removing the solvent from the upper layer film forming composition.

The upper layer film forming composition can be prepared by mixing the copolymer (X), an ether compound having 8 to 16 carbon atoms as a solvent, and as necessary, the additives according to the composition, and stirring and mixing the mixture at, for example, room temperature to 40° C.

### <Step (3)>

The step (3) is a step of subjecting the block copolymer to phase separation.

The phase separation of the block copolymer can be performed by treatment that results in rearrangement of the block copolymer, such as sonication, solvent treatment, or thermal annealing. In a lot of applications, it is desirable to achieve phase separation of the block copolymer simply by heating or so-called thermal annealing.

The thermal annealing can be performed under normal pressure, reduced pressure, or pressurized conditions in the air or in an inert gas.

The conditions for the thermal annealing are not particularly limited, and are preferably 180° C. to 300° C., more preferably 210° C. to 280° C., and particularly preferably 230° C. to 270° C., in the atmosphere.

The treatment time is not particularly limited, and is usually 1 minute to 30 minutes, and preferably 3 minutes to 10 minutes.

The phase separation of the block copolymer forms a block copolymer domain oriented substantially perpendicular to the substrate or underlayer film surface. The form of the domain is, for example, a lamellar shape, a spherical shape, a cylindrical shape, or the like. A domain interval is, for example, 50 nm or less. According to the production method of the substrate having the phase-separated pattern of the block copolymer of the present invention, it is possible to form a structure having a desired size, shape, orientation, and periodicity.

When the step of forming the upper layer film is performed between the step (2) and the step (3), the upper layer film can be peeled off after phase separation of the block copolymer is performed. The peeling can be performed, for example, using a solvent or a mixture of solvents (solvent for peeling) that does not damage, dissolve, or substantially swell the block copolymer. The peeled upper layer film can also be isolated and reused. The isolation can be performed, for example, by conventional means such as precipitation and distillation.

### (Manufacturing Method of Semiconductor Device)

A manufacturing method of a semiconductor device of the present invention includes the following steps (1) to (5).
Step (1): Step of forming an underlayer film on a substrate using the brush forming composition of the present invention
Step (2): Step of forming a layer containing a block copolymer on the underlayer film
Step (3): Step of subjecting the block copolymer to phase separation
Step (4): Step of removing a portion of the phase-separated block copolymer
Step (5): Step of etching the substrate

The manufacturing method of the semiconductor device preferably further includes a step of forming an upper layer film on the layer containing the block copolymer between the step (2) and the step (3).

The details of the steps (1) to (3) and the step of forming the upper layer film are as described in the production method of the substrate having a phase-separated pattern of a block copolymer of the present invention.

### <Step (4)>

The step (4) is a step of removing a portion of the phase-separated block copolymer.

The layer containing the phase-separated block copolymer has, for example, a plurality of phases including each of a plurality of kinds of blocks constituting the block copolymer. In the step (4), at least one phase of the plurality of phases is selectively removed.

Examples of the method for selectively removing the phase including the block include a method in which a layer containing the phase-separated block copolymer is subjected to oxygen plasma treatment and a method in which a layer containing the phase-separated block copolymer is subjected to hydrogen plasma treatment.

By performing the step (4), a three-dimensional pattern according to the form of the domain is formed from the layer containing the phase-separated block copolymer.

### <Step (5)>

The step (5) is a step of etching the substrate.

In the step (5), the substrate is selectively etched using the three-dimensional pattern obtained in the step (4) as a mask.

By using the three-dimensional pattern obtained from the layer containing the phase-separated block copolymer, it is possible to impart a desired shape to the substrate to be processed by etching and to manufacture a suitable semiconductor device.

In the etching, gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, or dichloroborane can be used.

A halogen-based gas is preferably used, and a fluorine-based gas is more preferably used. Examples of the fluorine-based gas include tetrafluoromethane (CF₄), perfluorocyclobutane (C₄F₈), perfluoropropane (C₃F₈), trifluoromethane, and difluoromethane (CH₂F₂)

### EXAMPLES

Next, the contents of the present invention will be specifically described with reference to Examples, but the present invention is not limited thereto.

The weight average molecular weight of the polymer shown in the following Synthesis Examples 1 and 2 of the present specification is a measurement result by gel permeation chromatography (hereinafter, abbreviated as GPC). For the measurement, a GPC apparatus manufactured by Tosoh Corporation is used, and the measurement conditions and the like are as follows.
GPC column: TSKgel Super-Multipore HZ-N (two columns)
Column temperature: 40° C.
Solvent: tetrahydrofuran (THF)
Flow rate: 0.35 ml/min
Standard sample: polystyrene (manufactured by Tosoh Corporation)

### Synthesis Example 1

4.41 g of 2-vinylnaphthalene (molar ratio to the entire polymer 1: 47%), 4.88 of 4-tert-butylstyrene (molar ratio to the entire polymer 1: 50%), 0.24 g of 2-hydroxyethyl methacrylate (molar ratio to the entire polymer 1: 3%), and 0.48 g of 2,2′-azobisisobutyronitrile were dissolved in 40.00 g of propylene glycol monomethyl ether acetate in a reaction vessel to obtain a solution. After replacing the reaction vessel with nitrogen, the solution was heated and stirred at 140° C. for about 18 hours. The reaction solution was added dropwise to methanol, and a precipitate was recovered by suction filtration and then dried at 60° C. under reduced pressure to recover a polymer 1. The weight average molecular weight Mw measured in terms of polystyrene by GPC was 9,200.

### Synthesis Example 2

4.58 g of 2-vinylnaphthalene (molar ratio to the entire polymer 2: 49%), 4.86 of 4-tert-butylstyrene (molar ratio to the entire polymer 2: 50%), 0.08 g of 2-hydroxyethyl methacrylate (molar ratio to the entire polymer 2: 1%), and 0.48 g of 2,2′-azobisisobutyronitrile were dissolved in 40.00 g of propylene glycol monomethyl ether acetate in a reaction vessel to obtain a solution. After replacing the reaction vessel with nitrogen, the solution was heated and stirred at 140° C. for about 18 hours. The reaction solution was added dropwise to methanol, and a precipitate was recovered by suction filtration and then dried at 60° C. under reduced pressure to recover a polymer 2. The weight average molecular weight Mw measured in terms of polystyrene by GPC was 10,500.

### Example 1

0.20 g of polystyrene having a hydroxyl group at the terminal (manufactured by POLYMER SOURCE INC., Mw=9,500, polydispersity=1.04) and 0.002 g of diazabicycloundecene (DBU: 1,8-diazabicyclo[5.4.0]undec-7-ene) were dissolved in 9.999 g of propylene glycol monomethyl ether and 9.999 g of propylene glycol monomethyl ether acetate. Thereafter, the solution was filtered using a polyethylene microfilter having a pore size of 0.02 μm to prepare a brush forming composition 1.

### Example 2

0.20 g of polystyrene having a hydroxyl group at the terminal (manufactured by POLYMER SOURCE INC., Mw=9,500, polydispersity=1.04) and 0.01 g of diazabicycloundecene (DBU: 1,8-diazabicyclo[5.4.0]undec-7-ene) were dissolved in 10.395 g of propylene glycol monomethyl ether and 10.395 g of propylene glycol monomethyl ether acetate. Thereafter, the solution was filtered using a polyethylene microfilter having a pore size of 0.02 μm to prepare a brush forming composition 2.

### Example 3

0.20 g of polystyrene having a hydroxyl group at the terminal (manufactured by POLYMER SOURCE INC., Mw=9,500, polydispersity=1.04) and 0.02 g of diazabicycloundecene (DBU: 1,8-diazabicyclo[5.4.0]undec-7-ene) were dissolved in 10.890 g of propylene glycol monomethyl ether and 10.890 g of propylene glycol monomethyl ether acetate. Thereafter, the solution was filtered using a polyethylene microfilter having a pore size of 0.02 μm to prepare a brush forming composition 3.

### Example 4

0.20 g of polystyrene having a hydroxyl group at the terminal (manufactured by POLYMER SOURCE INC., Mw=9,500, polydispersity=1.04) and 0.04 g of diazabicycloundecene (DBU: 1,8-diazabicyclo[5.4.0]undec-7-ene) were dissolved in 11.880 g of propylene glycol monomethyl ether and 11.880 g of propylene glycol monomethyl ether acetate. Thereafter, the solution was filtered using a polyethylene microfilter having a pore size of 0.02 μm to prepare a brush forming composition 4.

### Example 5

0.20 g of polystyrene having a hydroxyl group at the terminal (manufactured by POLYMER SOURCE INC., Mw=9,500, polydispersity=1.04) and 0.01 g of N-methylmorpholine (NMM) were dissolved in 10.395 g of propylene glycol monomethyl ether and 10.395 g of propylene glycol monomethyl ether acetate. Thereafter, the solution was filtered using a polyethylene microfilter having a pore size of 0.02 μm to prepare a brush forming composition 5.

### Example 6

0.20 g of polystyrene having a hydroxyl group at the terminal (manufactured by POLYMER SOURCE INC., Mw=9,500, polydispersity=1.04) and 0.01 g of N,N-dimethyl-4-aminopyridine (DMAP) were dissolved in 10.395 g of propylene glycol monomethyl ether and 10.395 g of propylene glycol monomethyl ether acetate. Thereafter, the solution was filtered using a polyethylene microfilter having a pore size of 0.02 μm to prepare a brush forming composition 6.

### Example 7

0.20 g of the polymer (polymer 1) obtained in Synthesis Example 1 and 0.01 g of diazabicycloundecene (DBU: 1,8-diazabicyclo[5.4.0]undec-7-ene) were dissolved in 10.395 g of propylene glycol monomethyl ether and 10.395 g of propylene glycol monomethyl ether acetate. Thereafter, the solution was filtered using a polyethylene microfilter having a pore size of 0.02 μm to prepare a brush forming composition 7.

### Example 8

0.20 g of the polymer (polymer 2) obtained in Synthesis Example 2 and 0.01 g of diazabicycloundecene (DBU: 1,8-diazabicyclo[5.4.0]undec-7-ene) were dissolved in 10.395 g of propylene glycol monomethyl ether and 10.395 g of propylene glycol monomethyl ether acetate. Thereafter, the solution was filtered using a polyethylene microfilter having a pore size of 0.02 μm to prepare a brush forming composition 8.

### Example 9

The brush forming composition 1 prepared in Example 1 was spin-coated on a silicon wafer, heated on a hot plate at 150° C. for 1 minute, and then immersed in propylene glycol monomethyl ether acetate at room temperature for 1 minute to remove a polymer not attached on the silicon wafer, thereby obtaining a brush attached film. The film thickness of the brush attached film after immersion was measured using an ellipso type film thickness measuring apparatus RE-3100 (SCREEN Co., Ltd.). The results were shown in Table 1.

### Examples 10 to 16

The film thickness of the brush attached film produced in the same manner as that of Example 9 was measured except that the brush forming compositions 2 to 8 prepared in Examples 2 to 8 were used instead of the brush forming composition 1. The results were shown in Tables 1 to 3.

### Comparative Example 1

0.20 g of polystyrene having a hydroxyl group at the terminal (manufactured by POLYMER SOURCE INC., Mw=9,500, polydispersity=1.04) was dissolved in 9.90 g of propylene glycol monomethyl ether and 9.90 g of propylene glycol monomethyl ether acetate. Thereafter, the solution was filtered using a polyethylene microfilter having a pore size of 0.02 μm to prepare a comparative composition 1.

### Comparative Example 2

0.20 g of the polymer (polymer 1) obtained in Synthesis Example 1 was dissolved in 9.90 g of propylene glycol monomethyl ether and 9.90 g of propylene glycol monomethyl ether acetate. Thereafter, the solution was filtered using a polyethylene microfilter having a pore size of 0.02 μm to prepare a comparative composition 2.

### Comparative Example 3

0.20 g of the polymer (polymer 2) obtained in Synthesis Example 2 was dissolved in 9.90 g of propylene glycol monomethyl ether and 9.90 g of propylene glycol monomethyl ether acetate. Thereafter, the solution was filtered using a polyethylene microfilter having a pore size of 0.02 μm to prepare a comparative composition 3.

### Comparative Examples 4 to 6

A brush attached film was prepared in the same manner as that of Example 9 except that the comparative compositions 1 to 3 prepared in Comparative Examples 1 to 3 were used instead of the brush forming composition 1. Then, the film thickness of the brush attached film was measured in the same manner as that of Example 9. The results were shown in Tables 1 to 3.

TABLE 1

| | | | After solvent immersion | |
|---|---|---|---|---|
| | | | | Attached |
| | | | | film |
| | | | | thickness |
| | | Additive | Attached | ratio (v.s. |
| | | (addition | film | Comparative |
| | Composition | amount) | thickness | Example 4) |
| Example 9 | Brush forming | DBU(1%) | 6.4 nm | 3.8 |
| | composition 1 | | | |
| Example 10 | Brush forming | DBU(5%) | 6.2 nm | 3.6 |
| | composition 2 | | | |
| Example 11 | Brush forming | DBU(10%) | 6.3 nm | 3.7 |
| | composition 3 | | | |
| Example 12 | Brush forming | DBU(20%) | 3.3 nm | 2.0 |
| | composition 4 | | | |
| Example 13 | Brush forming | NMM(5%) | 2.2 nm | 1.3 |
| | composition 5 | | | |
| Example 14 | Brush forming | DMAP(5%) | 2.3 nm | 1.4 |
| | composition 6 | | | |
| Comparative | Comparative | None | 1.7 nm | 1 |
| Example 4 | composition 1 | | | |

TABLE 2

| | | | After solvent immersion | |
|---|---|---|---|---|
| | | | | Attached |
| | | | | film |
| | | | | thickness |
| | | Additive | Attached | ratio (v.s. |
| | | (addition | film | Comparative |
| | Composition | amount) | thickness | Example 5) |
| Example 15 | Brush forming | DBU(5%) | 2.7 nm | 2.3 |
| | composition 7 | | | |
| Comparative | Comparative | None | 1.2 nm | 1 |
| Example 5 | composition 2 | | | |

TABLE 3

| | | | After solvent immersion | |
|---|---|---|---|---|
| | | | | Attached |
| | | | | film |
| | | | | thickness |
| | | Additive | Attached | ratio (v.s. |
| | | (addition | film | Comparative |
| | Composition | amount) | thickness | Example 6) |
| Example 16 | Brush forming | DBU(5%) | 2.5 nm | 2.3 |
| | composition 8 | | | |
| Comparative | Comparative | None | 1.1 nm | 1 |
| Example 6 | composition 3 | | | |

In the table, the addition amount (%) of the additive is mass % with respect to the brush polymer.

Table 1 shows the ratio of each attached film thickness to the attached film thickness of Comparative Example 4 as the attached film thickness ratio.

Table 2 shows the ratio of each attached film thickness to the attached film thickness of Comparative Example 5 as the attached film thickness ratio.

Table 3 shows the ratio of each attached film thickness to the attached film thickness of Comparative Example 6 as the attached film thickness ratio.

As shown in Tables 1 to 3, the brush material using the base component of the present invention as an additive can increase the thickness of the film attached onto the substrate.

1. A brush forming composition used to cause phase separation of a block copolymer of a layer containing the block copolymer formed on a substrate, the brush forming composition comprising:
a brush polymer,
an organic base, and
a solvent,
wherein the organic base is at least one of a compound represented by the following Formula (III), a compound represented by the following Formula (IV), a compound represented by the following Formula (V), 1,8-diazabicyclo[5.4.0]undecene-7, 1,5-diazabicyclo[4.3.0]nonene-5, 1,4-diazabicyclo[2.2.2]octane, 1,5,7-triazabicyclo[4.4.0]decene-5, and 7-methyl-1,5,7-triazabicyclo[4.4.0]decene-5: 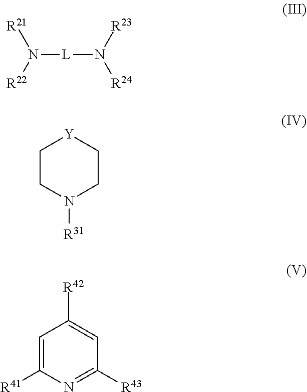
wherein:
in Formula (III), R²¹ to R²⁴ each independently represents a hydrogen atom, an alkyl group having 1 to 6 carbon atoms, or a hydroxyalkyl group having 1 to 6 carbon atoms, and L represents an alkylene group having 1 to 5 carbon atoms,
in Formula (IV), Y represents NR³², O, or S, R³¹ and R³² each independently represents a hydrogen atom, an alkyl group having 1 to 4 carbon atoms, a hydroxyalkyl group having 1 to 4 carbon atoms, an aminoalkyl group having 1 to 4 carbon atoms, or an alkyl sulfonate group having 1 to 4 carbon atoms, and
in Formula (V), R⁴¹ to R⁴³ each independently represents a hydrogen atom, an alkyl group having 1 to 6 carbon atoms, or —N(R⁵¹)(R⁵²) where R⁵¹ and R⁵² each independently represents a hydrogen atom or an alkyl group having 1 to 6 carbon atoms.

2. The brush forming composition according to claim 1, wherein the organic base contains a nitrogen atom.

3. The brush forming composition according to claim 1, wherein the organic base contains a nitrogen-containing ring.

4. The brush forming composition according to claim 1, wherein the organic base is at least one of N-methylmorpholine, N,N-dimethyl-4-aminopyridine, and 1,8-diazabicyclo[5.4.0]undecene-7.

5. The brush forming composition according to claim 1, wherein a content of the organic base is 0.1 mass % to 30 mass % with respect to the brush polymer.

6. The brush forming composition according to claim 1, wherein a content of the organic base is 0.5 mass % to 15 mass % with respect to the brush polymer.

7. The brush forming composition according to claim 1, wherein the brush polymer contains a functional group capable of binding to the substrate.

8. The brush forming composition according to claim 7, wherein the functional group capable of binding to the substrate is a hydroxy group, an amino group, or a sulfonic acid group.

9. The brush forming composition according to claim 1, wherein the brush polymer is an addition polymerization type polymer.

10. The brush forming composition according to claim 1, wherein the brush forming composition is an underlayer film forming composition for forming an underlayer film of the layer containing the block copolymer.

11. A substrate with an underlayer film obtained by exposing, to a solvent, a precursor film of an underlayer film obtained by applying a brush forming composition onto a substrate and heating the brush forming composition,
wherein the brush forming composition is used to cause phase separation of the block copolymer of the layer containing the block copolymer formed on the substrate,
wherein the brush forming includes a brush polymer, an organic base, and a solvent.

12. A production method of a substrate having a phase-separated pattern of a block copolymer, the production method comprising:
forming an underlayer film on a substrate using a brush forming composition;
forming a layer containing a block copolymer on the underlayer film; and
subjecting the block copolymer to phase separation,
wherein the brush forming composition is used to cause phase separation of the block copolymer of the layer containing the block copolymer formed on the substrate,
wherein the brush forming includes a brush polymer, an organic base, and a solvent.

13. The production method according to claim 12, further comprising forming an upper layer film on the layer containing the block copolymer between forming the layer containing the block copolymer on the underlayer film and subjecting the block copolymer to phase separation.

14. The production method according to claim 12, wherein the forming the underlayer film includes:
a treatment in which the brush forming composition is applied onto the substrate;
a treatment in which the brush forming composition applied onto the substrate is heated to form a precursor film of an underlayer film; and
a treatment in which the precursor film of the underlayer film is exposed to a solvent to obtain the underlayer film.

15. A manufacturing method of a semiconductor device, the manufacturing method comprising:
forming an underlayer film on a substrate using a brush forming composition;
forming a layer containing a block copolymer on the underlayer film;
subjecting the block copolymer to phase separation;
removing a portion of the phase-separated block copolymer; and
etching the substrate,
wherein the brush forming composition is used to cause phase separation of the block copolymer of the layer containing the block copolymer formed on the substrate, wherein the brush forming includes a brush polymer, an organic base, and a solvent.

16. The manufacturing method according to claim 15, further comprising forming an upper layer film on the layer containing the block copolymer between forming the layer containing the block copolymer on the underlayer film and subjecting the block copolymer to phase separation.

17. The manufacturing method according to claim 15, wherein the forming the underlayer film includes:
a treatment in which the brush forming composition is applied onto the substrate;
a treatment in which the brush forming composition applied onto the substrate is heated to form a precursor film of an underlayer film; and
a treatment in which the precursor film of the underlayer film is exposed to a solvent to obtain the underlayer film.
